(19) United States
(12) Patent Application Publication
(10) Pub. No.: US 2026/0287791 A1
(43) Pub. Date: Sep. 24, 2026

(54) COVER WINDOW AND ELECTRONIC DEVICE INCLUDING THE SAME

(71) Applicant: Samsung Display Co., LTD., Yongin-si (KR)

(72) Inventors: Ju Young YOON, Yongin-si (KR); Da Hye KIM, Yongin-si (KR); Hyeon Mi LEE, Yongin-si (KR); Hyun Hyang KIM, Yongin-si (KR); Man Soo KIM, Yongin-si (KR)

(21) Appl. No.: 19/378,871

(22) Filed: Nov. 4, 2025

(30) Foreign Application Priority Data
Mar. 24, 2025 (KR) 10-2025-0037109

(51) Int. Cl. G02B 1/115; G02B 1/14; G06F 1/16

(52) U.S. Cl. CPC G02B 1/115; G02B 1/14; G06F 1/1656

(57) ABSTRACT

A cover window includes, a front portion, and a peripheral portion bent from the front portion and disposed on one side of the front portion, a substrate, and a coating layer disposed on the substrate and including a first layer disposed at an uppermost position, a second layer disposed below the first layer, and a third layer disposed below the second layer, wherein the first layer includes a low-refractive-index layer, the second layer includes at least two high-refractive-index layers and a low-refractive-index layer disposed between the at least two high-refractive-index layers, and the third layer includes at least two low-refractive-index layers and a high-refractive-index layer disposed between the at least two low-refractive-index layers.

This application claims priority to Korean Patent Application No. 10-2025-0037109, filed on Mar. 24, 2025, and all the benefits accruing therefrom under 35 U.S.C. § 119, the content of which in its entirety is herein incorporated by reference.

### BACKGROUND

### 1. Field

The disclosure relates to a cover window and an electronic device including the same.

### 2. Description of the Related Art

With the development of multimedia, display devices continue to be increasingly important. Such display devices include a liquid crystal display (“LCD”), an organic light-emitting display (“OLED”), or the like.

Among them, an OLED has advantages such as a wide viewing angle, excellent contrast, and fast response speed.

Some OLEDs may have flexibility. To improve aesthetics, flexible display devices have emerged in which edge portions of the display area are bent with a predetermined curvature.

In accordance with this trend, studies on window members having a curved surface continue to be actively conducted. Accordingly, there is a demand for a window member that may fully cover the edge portions of a display area.

### SUMMARY

One feature of the disclosure is to provide a cover window and an electronic device including the same, in which the chroma of the front portion and the chroma of the peripheral portions are substantially identical.

The features of the disclosure are not limited to those mentioned above, and other objectives not explicitly stated will be clearly understood by those skilled in the art based on the following description.

In an embodiment of the disclosure, there is provided a cover window including a front portion, and a peripheral portion bent from the front portion and disposed on one side of the front portion, a substrate, and a coating layer disposed on the substrate and including a first layer disposed at an uppermost position, a second layer disposed below the first layer, and a third layer disposed below the second layer, wherein the first layer includes a low-refractive-index layer, the second layer includes at least two high-refractive-index layers and a low-refractive-index layer disposed between the at least two high-refractive-index layers, and the third layer includes at least two low-refractive-index layers and a high-refractive-index layer disposed between the at is least two low-refractive-index layers.

In an embodiment, ratios of tristimulus values of reflected light to tristimulus values of reference light in the peripheral portion are the same as ratios of tristimulus values of the reflected light to tristimulus values of the reference light in the front portion.

In an embodiment, chroma of the peripheral portion is the same as chroma of the front portion.

In an embodiment, a thickness of the coating layer in the peripheral portion is less than or equal to a thickness of the coating layer in the front portion.

In an embodiment, the first layer includes SiO₂, a thickness of the first layer is 80 nanometers (nm) to 120 nm, and a refractive index of the first layer is 1.4 to 1.55.

In an embodiment, the high-refractive-index layer includes at least one of ZrO₂, Ta₂O₅, Si₃N₄, TiO₂, or Ti₃O₅, a thickness of the high-refractive-index layer is 5 nm to 90 nm, and a refractive index of the high-refractive-index layer is 1.8 to 2.5.

In an embodiment, the low-refractive-index layer of the second layer includes at least one of SiO₂, Al₂O₃, or SiON, a thickness of the low-refractive-index layer is 5 nm to 90 nm, and a refractive index of the low-refractive-index layer is 1.45 to 1.7.

In an embodiment, the coating layer further includes a fingerprint-resistant layer disposed on the first layer, and the fingerprint-resistant layer includes perfluoropolyether (“PFPE”).

In an embodiment, the second layer includes a first high-refractive-index layer, a first low-refractive-index layer, and a second high-refractive-index layer, sequentially arranged from a side farther from the substrate, and a thickness of the first low-refractive-index layer is smaller than thicknesses of the first and second high-refractive-index layers.

In an embodiment of the disclosure, there is provided a cover window including a is front portion, and a peripheral portion bent from the front portion and disposed on one side of the front portion, a substrate, and a coating layer disposed on the substrate and including a first layer disposed at an uppermost position, a second layer disposed below the first layer, and a third layer disposed below the second layer, wherein the first layer includes a low-refractive-index layer, the second layer includes at least two high-hardness layers and at least one intermediate layer disposed between the at least two high-hardness layers, and the third layer includes at least two low-refractive-index layers and at least one high-refractive-index layer disposed between the at least two low-refractive-index layers.

In an embodiment, ratios of tristimulus values of reflected light to tristimulus values of reference light in the peripheral portion are the same as ratios of tristimulus values of the reflected light to tristimulus values of the reference light in the front portion.

In an embodiment, chroma of the peripheral portion is the same as chroma of the front portion.

In an embodiment, a thickness of the coating layer in the peripheral portion is less than or equal to a thickness of the coating layer in the front portion.

In an embodiment, the first layer includes SiO₂, a thickness of the first layer is 80 nm to 120 nm, and a refractive index of the first layer is 1.45 to 1.55.

In an embodiment, a high-hardness layer of the at least two high-hardness layers includes at least one of ZrO₂, Ta₂O₅, Si₃N₄, TiO₂, or Ti₃O₅, a thickness of the high-hardness layer is 40 nm to 500 nm, and a refractive index of the high-hardness layer is 1.8 to 2.1.

In an embodiment, the low-refractive-index layer includes at least one of SiO₂, Al₂O₃, or SiON, a thickness of the low-refractive-index layer is 100 nm or less, and a refractive is index of the low-refractive-index layer is 1.45 to 1.8.

In an embodiment, the coating layer further includes a fingerprint-resistant layer disposed on the first layer, and the fingerprint-resistant layer includes PFPE.

In an embodiment, the at least one intermediate layer includes at least two low-refractive-index layers and at least one high-refractive-index layer disposed between the at least two low-refractive-index layers of the at least one intermediate layer, and a thickness of the low-refractive-index layer of the at least one intermediate layer is smaller than a thickness of the high-hardness layer.

In an embodiment, a thickness of the low-refractive-index layer next (adjacent) to the high-hardness layer is smaller than a thickness of the high-hardness layer.

In an embodiment of the disclosure, there is provided an electronic device including a display device including a display panel and a cover window disposed on the display panel, a processor configured to provide an image driving signal to the display panel, and a power module configured to supply power to the display panel and the processor, wherein the cover window includes, a front portion, and a peripheral portion bent from the front portion and disposed on one side of the front portion, a substrate, and a coating layer disposed on the substrate and including a first layer disposed at an uppermost position, a second layer disposed below the first layer, and a third layer disposed below the second layer, the first layer includes a low-refractive-index layer, the second layer includes at least two high-refractive-index layers and a low-refractive-index layer disposed between the at least two high-refractive-index layers, and the third layer includes at least two low-refractive-index layers and a high-refractive-index layer disposed between the at least two low-refractive-index layers.

In accordance with the cover window and the electronic device including the same in an embodiment of the disclosure, it is possible that the chroma of the front portion and the is chroma of the peripheral portions are substantially identical.

It should be noted that the effects of the disclosure are not limited to those described above, and other effects of the disclosure will be apparent from the following description.

### BRIEF DESCRIPTION OF THE DRAWINGS

The above and other advantages and features of the disclosure will become more apparent by describing embodiments thereof in detail with reference to the attached drawings, in which:

FIG. 1 is a plan view illustrating embodiments of a display device;

FIG. 2 is a cross-sectional view taken along line X1-X1′ of FIG. 1;

FIG. 3 is a cross-sectional view illustrating an embodiment of a display panel;

FIG. 4A is a cross-sectional view illustrating an embodiment of a cover window;

FIG. 4B is an angle-based graph illustrating reflectance by wavelength of a cover window according to a comparative embodiment;

FIG. 5 is a block diagram illustrating a stacked structure of a cover window according to a first embodiment;

FIG. 6 is a detailed block diagram illustrating the stacked structure of the cover window according to the first embodiment;

FIG. 7A is a table illustrating the thickness of the front portion of the cover window according to the first embodiment;

FIG. 7B is a table illustrating chroma by angle of the peripheral portions of the cover window according to the first embodiment;

FIG. 8A is a table illustrating the thickness of the front portion of the cover window according to a comparative embodiment;

FIG. 8B is a table illustrating chroma by angle of the peripheral portions of the cover window according to the comparative embodiment;

FIG. 9 is an angle-based graph illustrating reflectance by wavelength at the peripheral portions of the cover window according to the first embodiment;

FIG. 10 is an angle-based graph illustrating reflectance by wavelength at the peripheral portions of the cover window according to the comparative embodiment;

FIG. 11 is a color-based graph illustrating differences in the reflectance of tristimulus values between the peripheral portions and the front portion by angle of the peripheral portions of the cover window according to the first embodiment;

FIG. 12 is a block diagram illustrating a stacked structure of a cover window according to a second embodiment;

FIG. 13 is a detailed block diagram illustrating the stacked structure of the cover window according to the second embodiment;

FIG. 14A is a table illustrating the thickness of the front portion of the cover window according to the second embodiment;

FIG. 14B is a table illustrating chroma by angle of the peripheral portions of the cover window according to the second embodiment;

FIG. 15 is a block diagram illustrating a stacked structure of a cover window according to a third embodiment;

FIG. 16 is a detailed block diagram illustrating the stacked structure of the cover window according to the third embodiment;

FIG. 17A is a table illustrating the thickness of the front portion of the cover window according to the third embodiment;

FIG. 17B is a table illustrating chroma by angle of the peripheral portions of the is cover window according to the third embodiment;

FIG. 18 is a block diagram illustrating a stacked structure of a cover window according to a fourth embodiment;

FIG. 19 is a detailed block diagram illustrating the stacked structure of the cover window according to the fourth embodiment;

FIG. 20A is a table illustrating the thickness of the front portion of the cover window according to the second embodiment;

FIG. 20B is a table illustrating chroma by angle of the peripheral portions of the cover window according to the second embodiment;

FIG. 21 is a block diagram of an embodiment of an electronic device; and

FIG. 22 is a set of schematic views of embodiments of electronic devices.

### DETAILED DESCRIPTION

The disclosure will now be described more fully hereinafter with reference to the accompanying drawings, in which preferred embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it may be directly on the other layer or substrate, or intervening layers may also be present. The same reference numbers indicate the same components throughout the specification.

It will be understood that, although the terms “first,” “second,” “third” etc. may be used herein to describe various elements, components, regions, layers and/or sections, these is elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” may therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” may, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” may mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, embodiments of the disclosure will be described in detail with reference to the accompanying drawings.

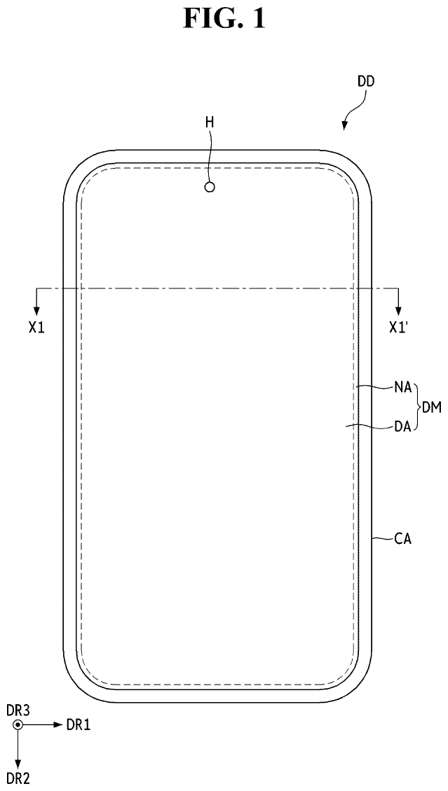

FIG. 1 is a plan view illustrating embodiments of a display device.

Referring to FIG. 1, a display device DD may be applied to a large-sized display device such as a television or monitor, as well as to a medium- and small-sized display device such as a smartphone, tablet, automotive navigation system, game console, or smartwatch. In this embodiment, the display device DD is illustrated as a smartphone.

The display device DD may have various shapes. In an embodiment, the display device DD may have a substantially quadrangular shape, e.g., rectangular shape in a plan view defined by a first direction DR1 and a second direction DR2, for example. In an embodiment, the display device DD may include two first sides extending in the first direction DR1 and two is second sides extending in the second direction DR2 on that plane, for example. In an embodiment, the first sides may be shorter than the second sides, but the disclosure is not limited thereto.

The first and second directions DR1 and DR2 may intersect each other and may both be horizontal directions. In an embodiment, the first and second directions DR1 and DR2 may be orthogonal to each other. A third direction DR3 may intersect the first and second directions DR1 and DR2 and may be a vertical direction orthogonal to the first and second directions DR1 and DR2, for example. Unless otherwise defined, in this specification, the direction indicated by the arrow for each of the first, second, and third directions DR1, DR2, and DR3 may be also referred to as one side or a first side, and the opposite direction may be also referred to as an opposite side or a second side. In addition, in this specification, the terms “top,” “upper side,” “upper portion,” “top surface,” and “upper surface” refer to the direction of the arrow for the third direction DR3 in the drawings, while “bottom,” “lower side,” “bottom portion,” and “bottom surface” refer to the opposite direction of the arrow for the third direction DR3.

The display device DD may have angled corners or rounded corners. In an embodiment, the corners where the first sides and the second sides of the display device DD meet may form a right angle or a curved surface.

The planar shape of the display device DD is not limited to that illustrated, and the display device DD may have various other shapes such as circular, elliptical, or another shape. In addition, FIG. 1 illustrates an embodiment where the front surface of the display device DD including a display area DA is flat, but the disclosure is not limited thereto. In an alternative embodiment, the front surface of the display device DD may be at least partially curved.

The display device DD may include a display module DM that includes a display panel. In an embodiment, the display device DD may further include additional components. In is an embodiment, the display device DD may include a case member CA for protecting the display module DM, for example.

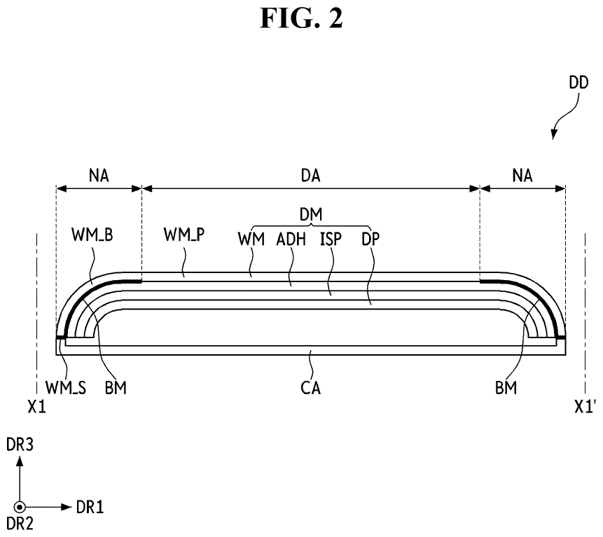

The display module DM may include the display area DA and a non-display area NA disposed around the display area DA. The display area DA may include pixels for displaying images. In an embodiment, a transmissive hole region H (e.g., a non-pixel region where pixels are not arranged, or a low-resolution region where pixels are arranged at relatively low resolution) corresponding to a camera or the like may be disposed in the display area DA, but the disclosure is not limited thereto. The non-display area NA may be disposed on at least one side of the display area DA and may partially or surround an entirety of the display area DA. In the non-display area NA, wirings and pads electrically connected to the pixels of the display area DA and/or at least one driving circuit may be arranged. The non-display area NA may be a region where a light-blocking portion BM (refer to FIG. 2) is disposed, i.e., a region overlapping with the light-blocking portion BM (refer to FIG. 2) in the third direction DR3.

The case member CA may be coupled to the display module DM to protect the display module DM from external impacts. In an embodiment, the case member CA may be disposed on the side surfaces and/or rear surface of the display device DD to surround the side surfaces and/or rear surface of the display module DM, for example.

FIG. 2 is a cross-sectional view taken along line X1-X1′ of FIG. 1.

Referring to FIG. 2 and further to FIG. 1, the display module DM may include a display panel DP, an input sensing panel ISP, an adhesive member ADH, and a cover window WM.

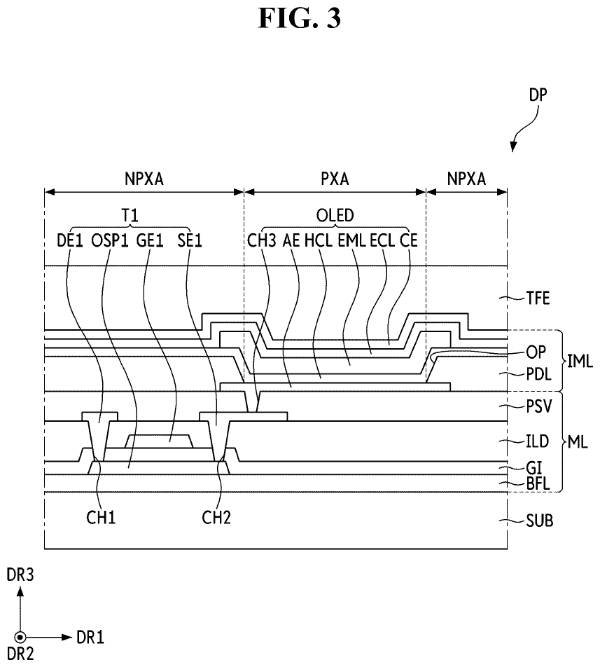

The display panel DP may include a light-emitting display panel. The light-emitting display panel may be an organic light-emitting display panel or a quantum dot light-emitting display panel, for example. The light-emitting layer of the organic light-emitting display panel is may include an organic light-emitting material. The light-emitting layer of the quantum-dot light-emitting display panel may include quantum dots or quantum rods. These are merely illustrative, and the display panel DP is not particularly limited. In an embodiment, the display panel DP may be an organic light-emitting display panel, which will be described later in greater detail with reference to FIG. 3.

The input sensing panel ISP may be disposed on the display panel DP. The input sensing panel ISP may be directly disposed on the display panel DP or may be bonded to the display panel DP via an adhesive member.

In an embodiment, the input sensing panel ISP may detect an external input by sensing a change in capacitance caused by an external object. In this case, the input sensing panel ISP may be also referred to as a capacitive-type input sensing panel. In other embodiments, the input sensing panel ISP may detect an external input by sensing a change in pressure caused by an external object. In this case, the input sensing panel ISP may be also referred to as a pressure-sensitive input sensing panel.

The input sensing panel ISP is illustrated as being configured separately from the display panel DP and disposed on or bonded to the display panel DP, but the disclosure is not limited thereto. In an embodiment, although not illustrated, instead of the input sensing panel ISP, a separate touch sensor layer may be embedded within the display panel DP, for example.

The adhesive member ADH may be disposed between the cover window WM and the input sensing panel ISP. The adhesive member ADH may bond the cover window WM and the input sensing panel ISP. The adhesive member ADH may include a general adhesive. In an embodiment, the adhesive member ADH may include a pressure-sensitive adhesive (“PSA”), an optical clear adhesive (“OCA”), or an optical clear resin (“OCR”), for example. In an embodiment, the adhesive member ADH may be omitted.

The cover window WM may be disposed on the adhesive member ADH. The cover window WM may cover the display panel DP. The cover window WM may fully cover the display area DA and the non-display area NA of the display device DD. The shape of the display panel DP may correspond to the shape of the cover window WM. The cover window WM may protect the display panel DP from external impacts and provide an input surface to the user.

The cover window WM may have a transparent property to allow light generated by the display panel DP to be transmitted. The cover window WM may include a glass or plastic material. In an embodiment, when the cover window WM includes glass, it may include chemically ion-exchanged strengthened glass. In other embodiments, when the cover window WM includes plastic, it may include a polyimide (“PI”) film.

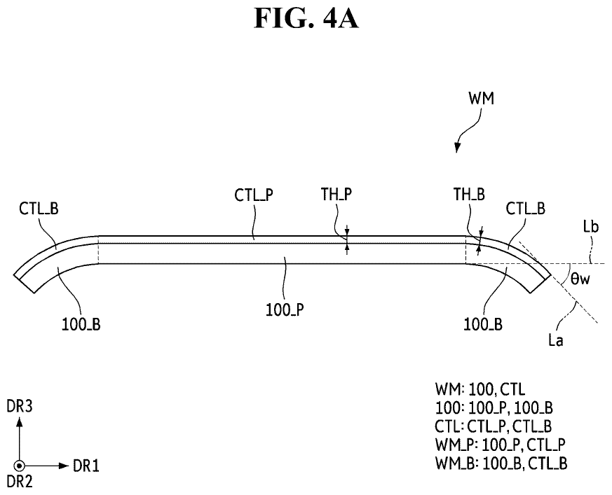

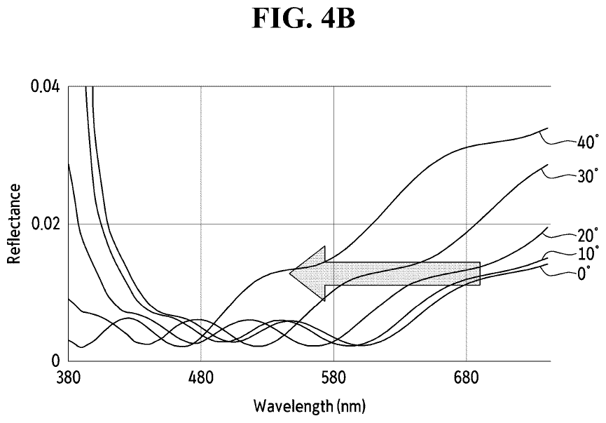

The cover window WM may include a front portion WM_P, peripheral portions WM_B, and side surfaces WM_S. The front portion WM_P may be substantially parallel to the horizontal directions defined by the first and second directions DR1 and DR2. The peripheral portions WM_B may surround the front portion WM_P and be portions bent from the front portion WM_P in the third direction DR3. The side surfaces WM_S surround the peripheral portions WM_B and refer to the sides of the edges disposed along the perimeter of the cover window WM. In an embodiment, the side surfaces WM_S may be surfaces connecting the top surface and the bottom surface of the cover window WM, for example. The cover window WM will be described later in further detail with reference to FIG. 4A or the like.

The light-blocking portion BM may be disposed in the non-display area NA. The light-blocking portion BM may be disposed in at least one of the front portion WM_P, the peripheral portions WM_B, and the side surface WM_S of the cover window WM. In an embodiment, the light-blocking portion BM may be placed in at least a part of the front portion WM_P, at least a part of the peripheral portions WM_B, and at least a part of the side surface is WM_S, for example.

The light-blocking portion BM may prevent light leakage at the outer periphery of the display device DD. By being disposed on the side surfaces WM_S that contact the case member CA, the light-blocking portion BM may improve the adhesive strength between the cover window WM and the case member CA.

The case member CA may be disposed below the display module DM. The case member CA may be next (adjacent) to the display area DA. The case member CA may have a predetermined color. The case member CA is disposed at the outermost periphery of the display device DD and may accommodate components therein. The case member CA may have a bottom surface and sidewalls extending from the bottom surface. An internal space defined by the bottom surface and the sidewalls may accommodate electronic modules (not illustrated). The electronic modules may include a camera, flash, fingerprint sensor, battery, and functional sensors, for example. The functional sensors may include a proximity sensor, a color concentration detection sensor, an illuminance sensor, a motion sensor, or a heart rate sensor, but are not limited thereto. In addition, some of the camera, flash, fingerprint sensor, battery, and functional sensors may be omitted, and other electronic modules may be further included.

The case member CA may include a material having relatively high hardness compared to the display module DM. In an embodiment, the case member CA may include glass, plastic, or metal, or any combinations thereof, and may include multiple frames and/or plates composed of such materials, for example. The case member CA may reliably protect the components of the display device DD from external impacts.

FIG. 3 is a cross-sectional view illustrating an embodiment of a display panel.

Referring to FIG. 3, the display panel DP may include a base layer SUB, a circuit element layer ML, a display element layer IML, and a thin-film encapsulation layer TFE. The is circuit element layer ML, the display element layer IML, and the thin-film encapsulation layer TFE may be sequentially disposed on the base layer SUB.

The base layer SUB may include glass or a synthetic resin film. Specifically, a synthetic resin layer may be formed on a carrier substrate used during the fabrication of the display panel DP. Then, a conductive layer, an insulating layer, or the like may be formed on the synthetic resin layer. Once the carrier substrate is removed, the synthetic resin layer may correspond to the base layer SUB. The synthetic resin layer may include a thermosetting resin. The synthetic resin layer may be a polyimide-based resin layer, but is not limited thereto. In addition, the base layer SUB may include an organic/inorganic composite material substrate or the like.

In this embodiment, the circuit element layer ML may include a buffer film BFL, which is an inorganic film, a first intermediate inorganic film GI, and a second intermediate inorganic film ILD, and may further include an intermediate organic film PSV. The materials of these inorganic and organic films are not particularly limited, and in an embodiment, the buffer film BFL may be optionally provided or omitted.

A semiconductor pattern OSP1 of a transistor T1 may be disposed on the buffer film BFL. The semiconductor pattern OSP1 may include or consist of amorphous silicon, polysilicon, or a metal oxide semiconductor.

The first intermediate inorganic film GI may be disposed on the semiconductor pattern OSP1. A control electrode GE1 of the transistor T1 may be disposed on the first intermediate inorganic film GI.

The second intermediate inorganic film ILD, covering the control electrode GE1, may be disposed on the first intermediate inorganic film GI. An input electrode DE1 and an output electrode SE1 of the transistor T1 may be disposed on the second intermediate inorganic is film ILD.

The input electrode DE1 and the output electrode SE1 may be electrically connected to the semiconductor pattern OSP1 through a first via hole CH1 and a second via hole CH2 penetrating the first intermediate inorganic layer GI and the second intermediate inorganic layer ILD, respectively. In an embodiment, the transistor T1 may be implemented as a bottom gate structure.

The intermediate organic film PSV, covering the input electrode DE1 and the output electrode SE1, may be disposed on the second intermediate inorganic film ILD. The intermediate organic film PSV may provide a planar surface.

The display element layer IML may be disposed on the intermediate organic film PSV. The display element layer IML may include a pixel defining layer PDL and an organic light-emitting diode OLED. The pixel defining layer PDL may include an organic material. A first electrode AE may be disposed on the intermediate organic film PSV. The first electrode AE may be connected to the output electrode SE1 through a third via hole CH3 penetrating the intermediate organic film PSV. An opening OP may be defined in the pixel defining layer PDL. The opening OP may expose at least a portion of the first electrode AE. In an embodiment, the pixel defining layer PDL may be omitted.

A hole control layer HCL may be disposed commonly in a light-emitting area PXA and a non-light-emitting area NPXA. A light-emitting layer EML may be disposed on the hole control layer HCL. The light-emitting layer EML may be disposed in a region corresponding to the opening OP. The light-emitting layer EML may include an organic material and/or an inorganic material. The light-emitting layer EML may generate light of a predetermined color.

An electron control layer ECL may be disposed on the light-emitting layer EML. A is second electrode CE may be disposed on the electron control layer ECL.

The thin-film encapsulation layer TFE may be disposed on the second electrode CE. The thin-film encapsulation layer TFE may cover the second electrode CE. A capping layer (not illustrated) covering the second electrode CE may be further provided between the thin-film encapsulation layer TFE and the second electrode CE. In this case, the thin-film encapsulation layer TFE may directly cover the capping layer.

FIG. 4A is a cross-sectional view illustrating an embodiment of a cover window. FIG. 4B is an angle-based graph illustrating reflectance by wavelength of a cover window according to a comparative embodiment.

Referring to FIGS. 4A and 4B, the cover window WM may include a front portion WM_P and peripheral portions WM_B.

The front portion WM_P may be substantially parallel to the horizontal directions defined by the first and second directions DR1 and DR2. Here, being substantially parallel to the horizontal directions defined by the first and second directions DR1 and DR2 encompasses not only when the front portion WM_P lies in a plane coinciding with the horizontal plane defined by the first and second directions DR1 and DR2, but also when the front portion WM_P is a substantially planar surface. In an embodiment, “substantially planar surface” may mean that the average radius of curvature of the front portion WM_P is approximately 100 millimeters (mm) or more, for example.

The peripheral portions WM_B may surround the front portion WM_P and may be disposed on one side of the front portion WM_P. The peripheral portions WM_B may be portions bent from the front portion WM_P in the third direction DR3. The average radius of curvature of the peripheral portions WM_B may be approximately 30 mm or less.

An angle defined between a tangent line La at a point on the peripheral portions WM_B and a straight line Lb extending in the extension direction of the front portion WM_P may be defined as a first angle θw. The first angle θw may become greater closer to the outer edges of the peripheral portions WM_B, i.e., away from the front portion WM_P. In an embodiment, the maximum value of the first angle θw may be approximately 45 degrees, but is not limited thereto.

In an embodiment, the first angle θw may be approximately 0 degrees at a point where the front portion WM_P and the peripheral portions WM_B meet, and may have the maximum value of approximately 45 degrees at the farthest points from the front portion WM_P on the respective peripheral portions WM_B, for example.

The cover window WM may include a substrate 100 and a coating layer CTL.

The substrate 100 may have a transparent property such that light generated from the display panel DP (refer to FIG. 2) may be transmitted therethrough. The substrate 100 may include a glass or plastic material. In an embodiment, when the substrate 100 includes glass, it may include chemically ion-exchanged strengthened glass. In other embodiments, when the substrate 100 includes plastic, it may include a PI film.

The substrate 100 may include a first front portion 100_P and first peripheral portions 100_B. The first front portion 100_P of the substrate 100 is included in the front portion WM_P of the cover window WM and corresponds to the substrate layer of the front portion WM_P. The first peripheral portions 100_B of the substrate 100 are included in the peripheral portions WM_B of the cover window WM and correspond to the substrate layers of the peripheral portions WM_B.

The coating layer CTL may enhance the screen visibility of the display device DD (refer to FIG. 1) and may provide functionalities such as waterproofing, water repellency, and oil is repellency. In an embodiment, the coating layer CTL may include an anti-reflection (“AR”) coating for reducing reflectance or an anti-fingerprint (AF) coating for preventing fingerprint smudges, for example.

The coating layer CTL may include a second front portion CTL_P and second peripheral portions CTL_B. The second front portion CTL_P of the coating layer CTL is included in the front portion WM_P of the cover window WM and corresponds to the coating layer portion of the front portion WM_P. The second peripheral portions CTL_B of the coating layer CTL are included in the peripheral portions WM_B of the cover window WM and correspond to the coating layer portions of the peripheral portions WM_B.

In an embodiment, a thickness TH_B of the second peripheral portions CTL_B of the coating layer CTL may be smaller than a thickness TH_P of the second front portion CTL_P of the coating layer CTL. In an embodiment, the thickness TH_B of the second peripheral portions CTL_B may be equal to the thickness TH_P of the second front portion CTL_P multiplied by the cosine of the first angle θw, for example. In an embodiment, the thickness TH_B of the second peripheral portions CTL_B may be approximately 0.7 to less than 1 times the thickness TH_P of the second front portion CTL_P.

The coating layer CTL may be formed by a deposition process. Since the first peripheral portions 100_B of the substrate 100 is inclined by the first angle θw with respect to the first front portion 100_P of the substrate 100, the deposition thickness of the coating layer CTL on the first peripheral portions 100_B of the substrate 100 may be smaller than the deposition thickness of the coating layer CTL on the first front portion 100_P of the substrate 100. Accordingly, the thickness TH_B of the second peripheral portions CTL_B of the coating layer CTL may be smaller than the thickness TH_P of the second front portion CTL_P of the is coating layer CTL.

As the first angle θw increases toward the edges of the peripheral portions WM_B of the cover window WM, the cosine value of the first angle θw decreases, and accordingly, the thickness TH_B of the second peripheral portions CTL_B may also decrease.

In this case, as the thickness of the second peripheral portions CTL_B of the coating layer CTL decreases, the optical path difference of reflected light decreases, and, as depicted in FIG. 4B, the reflection spectrum may shift toward the short-wavelength range. As a result, the reflectance of long-wavelength light increases, and the peripheral portions WM_B of the cover window WM may appear reddish. That is, the chroma of the peripheral portions WM_B of the cover window WM may become higher than that of the front portion WM_P.

In the cover window WM, despite such a short-wavelength shift, the chroma (e.g., C_{B}*) of the peripheral portions WM_B of the cover window WM may be substantially identical to the chroma (e.g., C_{P}*) of the front portion WM_P of the cover window WM. In an embodiment, the reflectance (e.g., R_{B}) of tristimulus values in the peripheral portions WM_B of the cover window WM may be substantially identical to the reflectance (e.g., R_{P}) of tristimulus values in the front portion WM_P of the cover window WM, for example. In other words, the ratios of the tristimulus values (e.g., X_B, Y_B, and Z_B) of reflected light to the tristimulus values (e.g., Xₙ, Yₙ, and Zₙ) of reference light in the peripheral portions WM_B of the cover window WM, i.e.,

$$\frac{X\_B}{{X}_{n}} , \frac{Y\_B}{{Y}_{n}} , and \frac{Z\_B}{{Z}_{n}} ,$$

may be identical to the ratios of tristimulus values (e.g., X_P, Y_P, and Z_P) of the reflected light to the tristimulus values (e.g., Xₙ, Yₙ, and Zₙ) of the reference light in the front portion WM_P of the cover window WM, i.e.,

$$\frac{X\_P}{{X}_{n}} , \frac{Y\_P}{{Y}_{n}} , and \frac{Z\_P}{{Z}_{n}} .$$

Here, tristimulus values refer to basic elements numerically representing color in the CIE 1976 color space (or the CIE 1931 color space) and indicate values defined based on human visual characteristics. Tristimulus values are calculated as a weighted sum of the reflectance of is an object (e.g., reflectance spectrum R) under a predetermined light source (e.g., the spectrum S of the D65 standard light source) and the color sensitivity of the human eye (e.g., standard observer functions x̅, y̅, and z̅) in the visible light range (e.g., approximately 380 nanometers (nm) to 780 nm wavelength range).

Since the spectrum S of the D65 standard light source and the standard observer functions x̅, y̅, and z̅ are constants, the tristimulus values (X_B, Y_B, and Z_B or X_P, Y_P, and Z_P) of the reflected light are proportional to the reflectance (e.g., R_{B} or R_{P}) of tristimulus values. Therefore, when the reflectance R_{B} in the peripheral portions WM_B of the cover window WM and the reflectance R, in the front portion WM_P of the cover window WM are identical, then the tristimulus values X_B, Y_B, and Z_B of the reflected light in the peripheral portions WM_B of the cover window WM and the tristimulus values X_P, Y_P, and Z_P of the reflected light in the front portion WM_P of the cover window WM may be identical.

In the color space, the chroma C_{B}* or C_{P}* is defined as a function of a* and b* components, and the a* and b* components are each defined as a function of the ratio of the tristimulus values of the reflected light to the tristimulus values of the reference light

$$( \frac{X\_B}{{X}_{n}} , \frac{Y\_B}{{Y}_{n}} , and \frac{Z\_B}{{Z}_{n}} or \frac{X\_P}{{X}_{n}} , \frac{Y\_P}{{Y}_{n}} , and \frac{Z\_P}{{Z}_{n}} ) .$$

Therefore, when X_B, Y_B, and Z_B are identical to X_P, Y_P, and Z_P or when

$$\frac{X\_B}{{X}_{n}} , \frac{Y\_B}{{Y}_{n}} , and \frac{Z\_B}{{Z}_{n}}$$

and are identical to

$$\frac{X\_P}{{X}_{n}} , \frac{Y\_P}{{Y}_{n}} , and \frac{Z\_P}{{Z}_{n}} ,$$

then the a* and b* components in the peripheral portions WM_B may be identical to those in the front portion WM_P because the tristimulus values Xₙ, Yₙ, and Zₙ of the reflected light are constants. Accordingly, the chroma C_{B}* in the peripheral portions WM_B may be identical to the chroma C,* in the front portion WM_P may be identical.

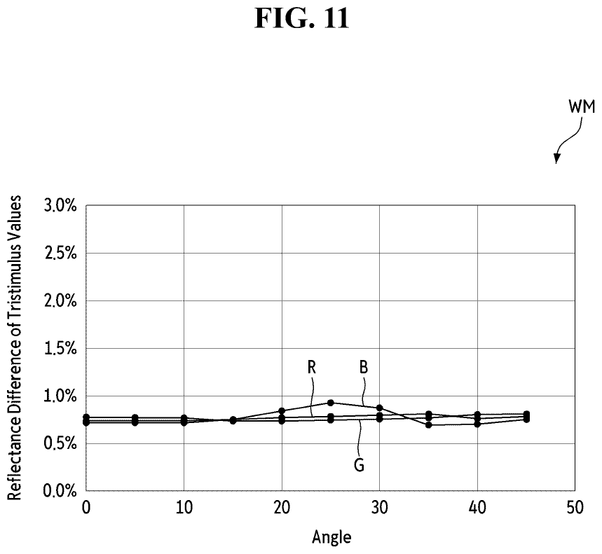

In this specification, the identity of chroma, the identity of the reflectance of tristimulus values, and the identity of the ratios of the tristimulus values of reflected light to the ratios of the tristimulus values of reference light between the front portion WM_P and the is peripheral portions WM_B of the cover window WM may be determined based on whether the reflectance of tristimulus values is identical between the front portion WM_P and the peripheral portions WM_B. When the difference in the reflectance of tristimulus values between the front portion WM_P and the peripheral portions WM_B is approximately less than 1% (refer to FIG. 11), then the reflectance of tristimulus values may be considered substantially identical between the front portion WM_P and the peripheral portions WM_B, and the chroma and the ratios of the tristimulus values of the reflected light to the ratios of the tristimulus values of the reference light may also be considered identical between the front portion WM_P and the peripheral portions WM_B.

In an embodiment, the chroma C_{B}* in the peripheral portions WM_B and the chroma C_{P}* in the front portion WM_P may each be approximately 10 or less, and preferably, approximately 4 or less. Here, the term “chroma” refers to the chroma value in the CIE 1976 color space.

A stacked structure of the cover window WM satisfying such conditions will hereinafter be described.

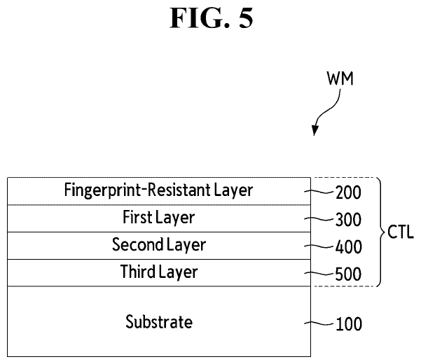

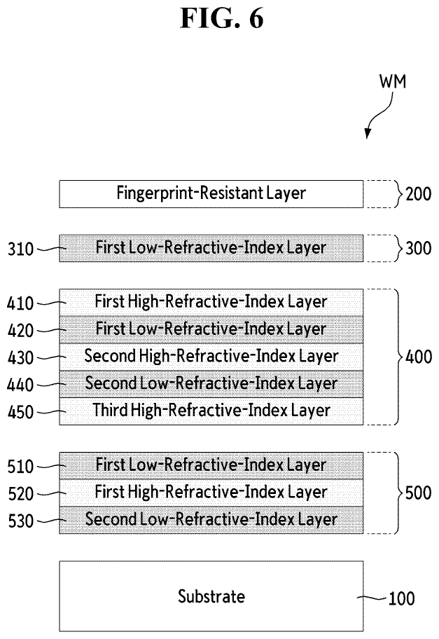

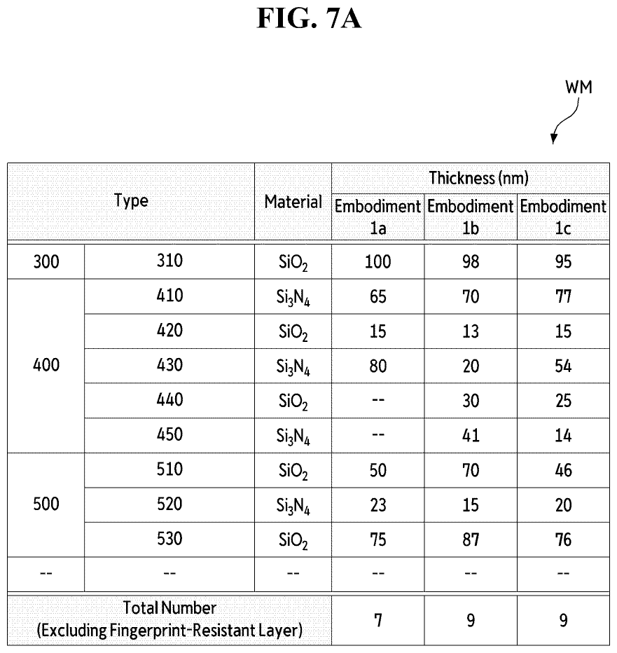

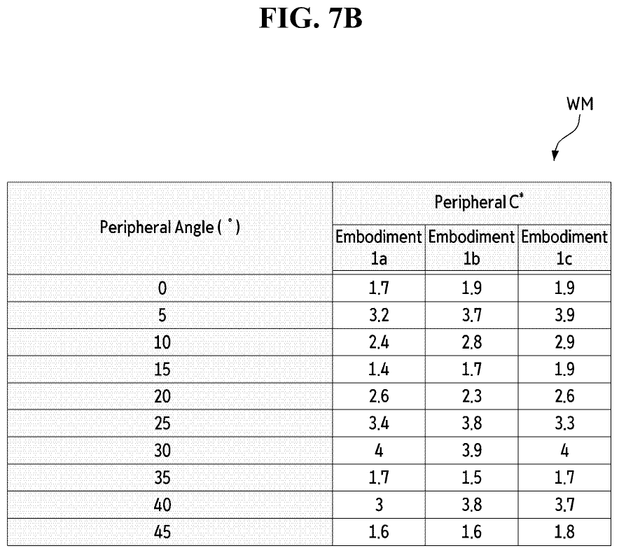

FIG. 5 is a block diagram illustrating a stacked structure of a cover window according to a first embodiment. FIG. 6 is a detailed block diagram illustrating the stacked structure of the cover window according to the first embodiment. FIG. 7A is a table illustrating the thickness of the front portion of the cover window according to the first embodiment. FIG. 7B is a table illustrating chroma by angle of the peripheral portions of the cover window according to the first embodiment.

Referring to FIGS. 5 through 7B and further to FIGS. 2 and 4A, a cover window WM according to the first embodiment may include a substrate 100 and a coating layer CTL.

The substrate 100 may have a transparent property such that light generated from the display panel DP may be transmitted therethrough. The substrate 100 may include a glass or plastic material. In an embodiment, when the substrate 100 includes glass, it may include chemically ion-exchanged strengthened glass. In other embodiments, when the substrate 100 includes plastic, it may include a PI film.

The coating layer CTL may be disposed on the substrate 100. The coating layer CTL may enhance screen visibility of the display device DD and may provide functionalities such as waterproofing, water repellency, and oil repellency. In an embodiment, the coating layer CTL may include an AR coating layer for reducing reflectance or an AF coating layer for preventing fingerprint smudges, for example.

In an embodiment, the coating layer CTL may include a fingerprint-resistant layer 200 as the AF coating layer and first, second, and third layers 300, 400, and 500 as the AR coating layer.

The fingerprint-resistant layer 200 may be disposed as the uppermost layer of the cover window WM. The fingerprint-resistant layer 200 may not only prevent fingerprints from remaining on the surface of the cover window WM but also provide functionalities such as waterproofing, water repellency, and oil repellency. In an embodiment, the fingerprint-resistant layer 200 may include perfluoropolyether (“PFPE”), but is not limited thereto. The thickness of the fingerprint-resistant layer 200 may be approximately 5 nm to 20 nm, and preferably about 6 nm, but is not limited thereto.

The AR coating layer may be disposed between the substrate 100 and the fingerprint-resistant layer 200. The AR coating layer may have a structure in which low- and high-refractive-index layers are alternately stacked. The AR coating layer may reduce external reflectance to improve visibility of the display device DD.

The AR coating layer may include first, second, and third layers 300, 400, and 500 sequentially arranged in a direction from the fingerprint-resistant layer 200 toward the substrate 100. That is, the substrate 100, the third layer 500, the second layer 400, the first layer 300, and the fingerprint-resistant layer 200 may be sequentially stacked.

The first layer 300 may include one low-refractive-index layer. In an embodiment, the first layer 300 may include a first low-refractive-index layer 310.

The second layer 400 may have a stacked structure in which a low-refractive-index layer is disposed between at least two high-refractive-index layers. The second layer 400 may include high-refractive-index layers at its uppermost and lowermost positions, and a low-refractive-index layer placed between the high-refractive-index layers, or have a structure in which low- and high-refractive-index layers are alternately arranged. The second layer 400 may include an odd number of layers in total. In an embodiment, the second layer 400 may include three layers, which may be arranged in the order of high/low/high refractive index, for example. In another embodiment, the second layer 400 may include five layers, which may be arranged in the order of high/low/high/low/high refractive index. The second layer 400 is illustrated as including three layers or five layers, but is not limited thereto. That is, in an alternative embodiment, the second layer 400 may include more than five layers. In an embodiment, the second layer 400 may include a first high-refractive-index layer 410, a first low-refractive-index layer 420, a second high-refractive-index layer 430, a second low-refractive-index layer 440, and a third high-refractive-index layer 450 that are sequentially arranged in the direction from the fingerprint-resistant layer 200 toward the substrate 100.

The third layer 500 may have a stacked structure in which a high-refractive-index layer is disposed between at least two low-refractive-index layers. The third layer 500 may include low-refractive-index layers at the uppermost and lowermost positions, and a high-refractive-index layer disposed between the low-refractive-index layers, or have a structure in which high- and low-refractive-index layers are alternately arranged. The third layer 500 may include an odd number of layers in total. In an embodiment, the third layer 500 may include three layers, which may be arranged in the order of low/high/low refractive index, for example. The third layer 500 is illustrated as including three layers, but is not limited thereto. That is, in an alternative embodiment, the third layer 500 may include more than three layers. In an embodiment, the third layer 500 may include a first low-refractive-index layer 510, a first high-refractive-index layer 520, and a second low-refractive-index layer 530 that are sequentially arranged in the direction from the fingerprint-resistant layer 200 toward the substrate 100.

In an embodiment, the low-refractive-index layer at the lowermost position of the third layer 500 may improve adhesion to the substrate 100. In an embodiment, the lowermost low-refractive-index layer of the third layer 500 and the substrate 100 may include the same material (e.g., SiO₂), and thus the adhesion between the third layer 500 and the substrate 100 may be enhanced through the lowermost low-refractive-index layer of the third layer 500, for example.

Due to the stacked structure of the first, second, and third layers 300, 400, and 500, the AR coating layer may overall have a stacked structure in which a high-refractive-index layer is disposed between at least two low-refractive-index layers. Overall, the AR coating layer may include low-refractive-index layers at the uppermost and lowermost positions, with high-refractive-index layers and low-refractive-index layers alternately arranged between the low-refractive-index layers. The AR coating layer may include an odd number of low- and high-refractive-index layers in total.

The low-refractive-index layer of the first layer 300, e.g., the first low-refractive-index layer 310, may include SiO₂. The refractive index of the low-refractive-index layer of the first layer 300 may be approximately 1.45 to 1.55. The thickness of the low-refractive-index layer of the first layer 300 may be approximately 80 nm to 120 nm.

In this specification, refractive index refers to absolute refractive index measured using the sodium D-line (λ≈589 nm, yellow) under standard conditions (at a temperature of 20±15° C. and a humidity of 65±20%). In an embodiment, refractive index may be absolute refractive index measured at 25° C. and 65% relative humidity using a refractometer (e.g., Ellipsometer M-2000, J. A. Woollam) in accordance with the Cauchy film model, based on a wavelength of 589 nm, for example.

The high-refractive-index layers of the second and third layers 400 and 500, e.g., the first, second, and third high-refractive-index layers 410, 430, and 450 of the second layer 400 and the first high-refractive-index layer 520 of the third layer 500, may include at least one of ZrO₂, Ta₂O₅, Si₃N₄, TiO₂, or Ti₃O₅. The refractive index of the second and third layers 400 and 500 may be approximately 1.8 to 2.5. The thickness of the second and third layers 400 and 500 may be approximately 5 nm to 90 nm.

The low-refractive-index layers of the second and third layers 400 and 500, e.g., the first and second low-refractive-index layers 420 and 440 of the second layer 400 and the first and third low-refractive-index layers 510 and 530 of the third layer 500, may include at least one of SiO₂, Al₂O₃, or SiON. The refractive index of the second and third layers 400 and 500 may be approximately 1.45 to 1.7. The thickness of the second and third layers 400 and 500 may be approximately 5 nm to 90 nm.

In an embodiment, the AR coating layer of the cover window WM may be formed by an electron beam (E-beam) deposition method.

FIG. 7A shows three embodiments of the first embodiment, i.e., Embodiments 1a, 1b, and 1c. The AR coating layer of a cover window WM according to Embodiment 1a includes a total of seven layers, the AR coating layer of a cover window WM according to Embodiment 1b includes a total of nine layers, and the AR coating layer of a cover window WM according to Embodiment 1c includes a total of nine layers.

In an embodiment, as shown in FIG. 7A, in the second layer 400 of each of the cover windows WM according to Embodiments 1a, 1b, and 1c, the thickness of the first low-refractive-index layer 420 may be smaller than the thicknesses of the first and second high-refractive-index layers 410 and 430. That is, the thickness of the first stack with a high/low/high structure in the second layer 400 may decrease and then increase again.

Furthermore, after the first stack, the thicknesses of the low- or high-refractive-index layers in the second layer 400 may continuously decrease or increase. In an embodiment, in the second layer 400 of the cover window WM according to Embodiment 1b, the thickness of the second low-refractive-index layer 440 may be greater than that of the second high-refractive-index layer 430, and the thickness of the third high-refractive-index layer 450 may be greater than that of the second low-refractive-index layer 440, for example. In another embodiment, in the second layer 400 of the cover window WM according to Embodiment 1c, the thickness of the second low-refractive-index layer 440 may be smaller than that of the second high-refractive-index layer 430, and the thickness of the third high-refractive-index layer 450 may be smaller than that of the second low-refractive-index layer 440.

In an embodiment, as shown in FIG. 7A, in the third layer 500 of each of the cover windows WM according to Embodiments 1a, 1b, and 1c, the thickness of the first high-refractive-index layer 520 may be smaller than the thicknesses of the first and second low-refractive-index layers 510 and 530. That is, the thickness of the stack with a high/low/high is structure in the third layer 500 may decrease and then increase again.

According to the cover window WM of the first embodiment, the chroma of the peripheral portions WM_B may be maintained at the same level as that of the front portion WM_P, even when the thickness of the second peripheral portions CTL_B of the coating layer CTL varies depending on the first angle θw of the peripheral portions WM_B, by adjusting the thicknesses, stacking order, and refractive indices of the low-refractive-index layers and high-refractive-index layers. In an embodiment, as shown in FIG. 7B, the chroma of the peripheral portions WM_B may be maintained at approximately 4 or less, for example.

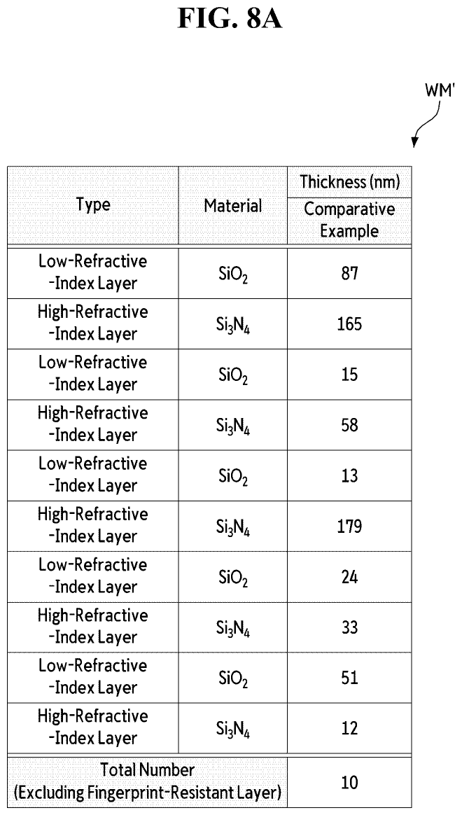

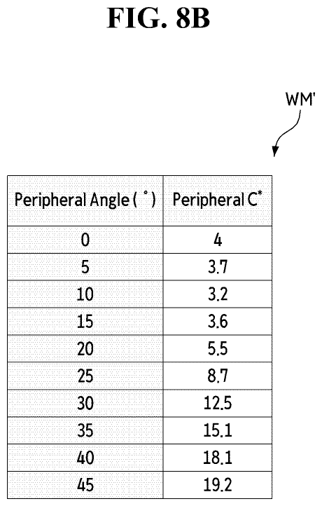

FIG. 8A is a table illustrating the thickness of the front portion of a cover window according to a comparative embodiment. FIG. 8B is a table illustrating chroma by angle of the peripheral portions of the cover window according to the comparative embodiment.

Referring to FIGS. 8A and 8B and further to FIG. 7B, in a cover window WM′ according to a comparative example, some of the high-refractive-index layers have a thickness greater than 90 nm, and the lowermost layer is a high-refractive-index layer. The stack of low/high/low refractive-index layers directly above the lowermost layer in the cover window WM′ according to the comparative example has a structure where the thickness increases toward the bottom, unlike in the third layers 500 of the cover windows WM according to Embodiments 1a, 1b, and 1c.

According to the comparative embodiment, the chroma of the peripheral portions increases as the angle of the peripheral portions increases. The chroma exceeds 4 at a peripheral portion angle of 20 degrees or greater.

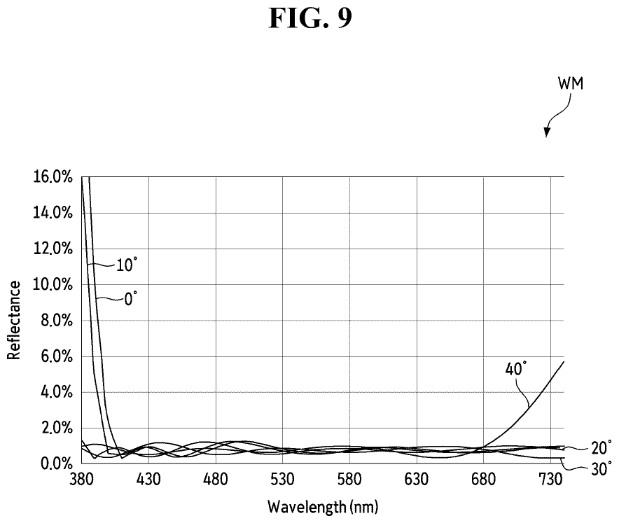

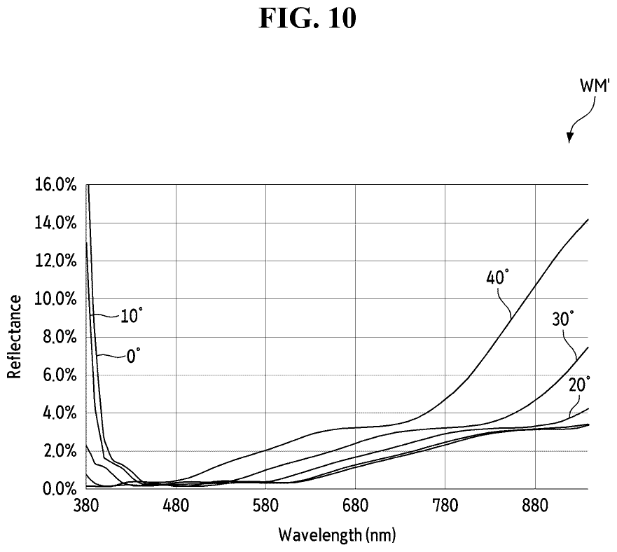

FIG. 9 is an angle-based graph illustrating reflectance by wavelength at the is peripheral portions of the cover window according to the first embodiment. FIG. 10 is an angle-based graph illustrating reflectance by wavelength at the peripheral portions of the cover window according to the comparative embodiment. FIG. 11 is a color-based graph illustrating differences in the reflectance of tristimulus values between the peripheral portions and front portion by angle of the peripheral portions of the cover window according to the first embodiment.

Referring to FIGS. 9 through 11, the reflectance spectrum of the peripheral portions of the comparative cover window WM′ shifts more toward the short-wavelength range as the peripheral portion angle increases, due to a greater thickness reduction. Accordingly, the reflectance increases with angle and exceeds 1% across most of the wavelength range.

Conversely, in the cover window WM according to the first embodiment, despite the short-wavelength shift, the reflectance at peripheral portion angles of 0°, 10°, 20°, 30°, and 40° remains approximately within 1% across most of the wavelength range. Therefore, the reflectance at the peripheral portions is low, and the chroma of the cover window WM according to the first embodiment may also be reduced.

In addition, FIG. 11 illustrates the difference in tristimulus reflectance between the front and peripheral portions by angle of the peripheral portions of the cover window WM in the illustrated embodiment. Even as the angle of the peripheral portions increases, the difference in the reflectance of tristimulus values between the front portion and peripheral portions at each peripheral portion angle remains under 1%. Thus, the chroma between the front portion and peripheral portions may be considered substantially identical.

Other embodiments of the display device of the disclosure will hereinafter be described, focusing on the differences from the aforementioned embodiments. Identical reference numerals represent identical elements throughout this specification, and thus, redundant descriptions thereof will be omitted or simplified.

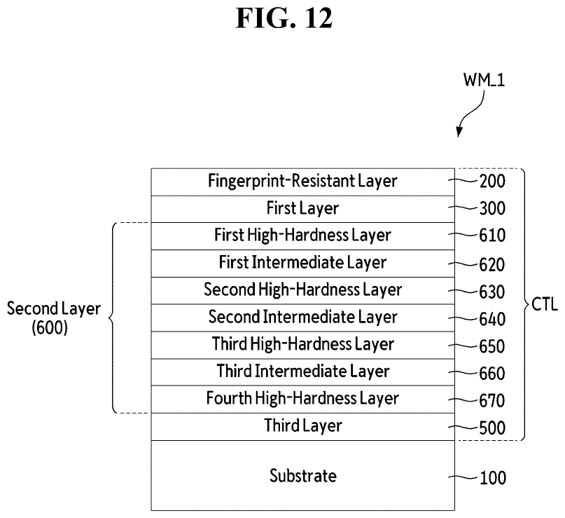

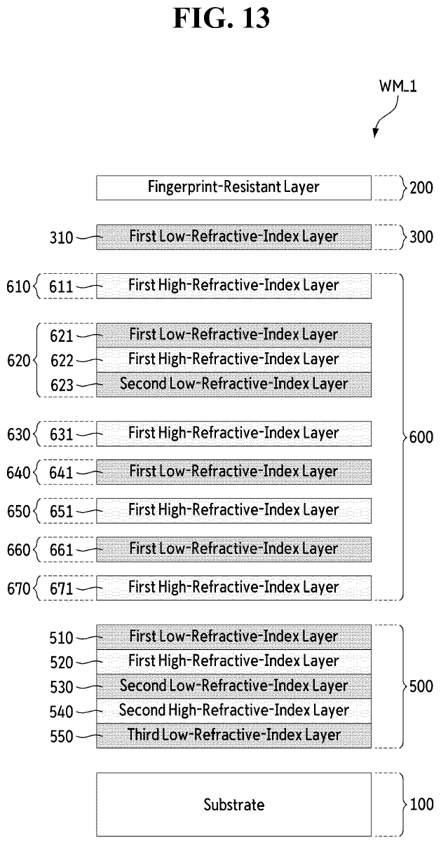

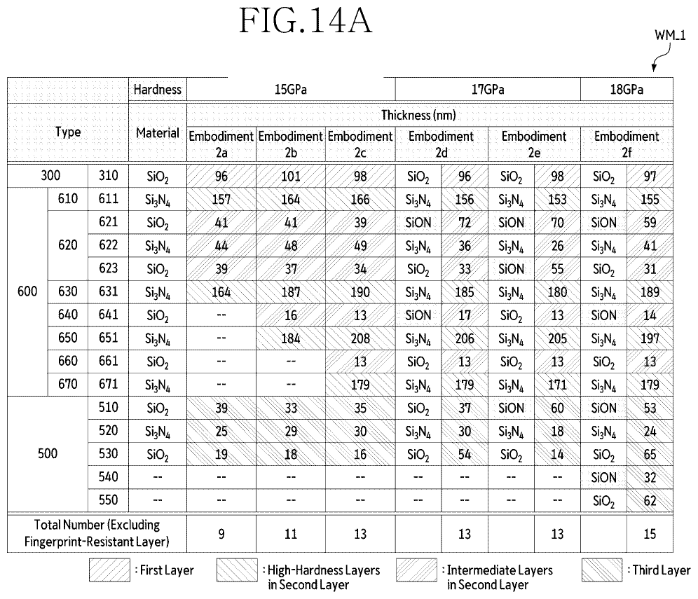

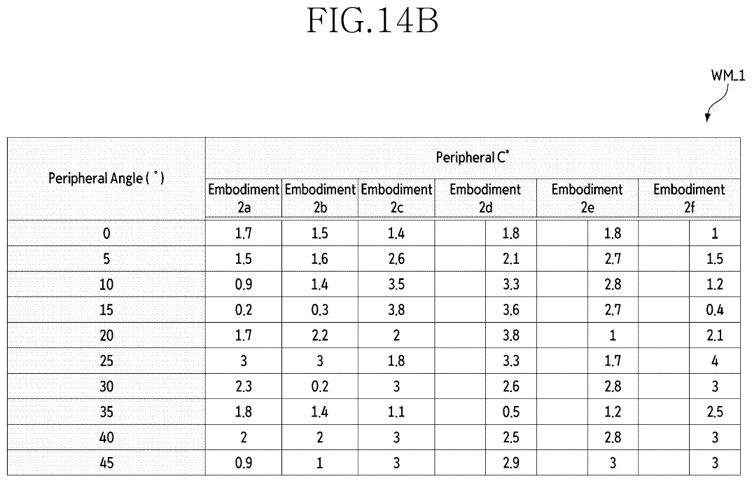

FIG. 12 is a block diagram illustrating a stacked structure of a cover window according to a second embodiment. FIG. 13 is a detailed block diagram illustrating the stacked structure of the cover window according to the second embodiment. FIG. 14A is a table illustrating the thickness of the front portion of the cover window according to the second embodiment. FIG. 14B is a table illustrating chroma by angle of the peripheral portions of the cover window according to the second embodiment.

Referring to FIGS. 12, 13, 14A, and 14B, a cover window WM_1 according to the second embodiment differs from the cover window WM according to the first embodiment described with reference to FIG. 5 in the structure of a second layer 600.

Specifically, an AR coating layer of a coating layer CTL may include first, second, and third layers 300, 600, and 500 sequentially arranged in a direction from a fingerprint-resistant layer 200 toward a substrate 100.

The first layer 300 may include one low-refractive-index layer. In an embodiment, the first layer 300 may include a first low-refractive-index layer 310.

The second layer 600 may have a stacked structure in which an intermediate layer is disposed between at least two high-hardness layers. The second layer 600 may include high-hardness layers at the uppermost and lowermost positions, and an intermediate layer disposed between the high-hardness layers, or have a structure in which an intermediate coating layer and a high-hardness layer are alternately arranged.

The second layer 600 may include an odd number of layers in total, combining high-hardness and intermediate layers. In an embodiment, the second layer 600 includes seven layers in total, which may be arranged in the order of hard/intermediate/hard/intermediate/hard/intermediate/hard, for example. The second layer 600 is illustrated as including seven layers in an embodiment, but is not limited thereto and may include fewer or more layers.

In an embodiment, the second layer 600 may include a first high-hardness layer 610, a first intermediate layer 620, a second high-hardness layer 630, a second intermediate layer 640, a third high-hardness layer 650, a third intermediate layer 660, and a fourth high-hardness layer 670, sequentially arranged in a direction from the fingerprint-resistant layer 200 toward the substrate 100.

The high-hardness layers of the second layer 600 may each include one high-refractive-index layer. The intermediate layers of the second layer 600 may include either a low-refractive-index layer or a stacked structure in which a high-refractive-index layer is disposed between at least two low-refractive-index layers. The intermediate layers may each consist of only a low-refractive-index layer, or include low-refractive-index layers at the uppermost and lowermost positions and a high-refractive-index layer disposed between the low-refractive-index layers, or have a structure in which low- and high-refractive-index layers are alternately stacked.

The intermediate layers of the second layer 600 may each include an odd number of layers in total, combining high- and low-refractive-index layers. In an embodiment, the intermediate layers of the second layer 600 may each include one layer, which may be a low-refractive-index layer, or three layers, which may be arranged in the order of low/high/low refractive index, for example. The intermediate layers of the second layer 600 are illustrated as each including one layer or three layers, but are not limited thereto and may each include more than three layers.

In an embodiment, the first high-hardness layer 610 of the second layer 600 may include a first high-refractive-index layer 611. The first intermediate layer 620 may include a first low-refractive-index layer 621, a first high-refractive-index layer 622, and a second low-refractive-index layer 623, sequentially arranged in the direction from the fingerprint-resistant layer 200 toward the substrate 100. The second high-hardness layer 630 may include a first high-refractive-index layer 631. The second intermediate layer 640 may include a first low-refractive-index layer 641. The third high-hardness layer 650 may include a first high-refractive-index layer 651. The third intermediate layer 660 may include a first low-refractive-index layer 661. The fourth high-hardness layer 670 may include a first high-refractive-index layer 671.

The third layer 500 may have a stacked structure in which a high-refractive-index layer is disposed between at least two low-refractive-index layers. The third layer 500 may include low-refractive-index layers at the uppermost and lowermost positions, and a high-refractive-index layer disposed between the low-refractive-index layers, or have a structure in which low- and high-refractive-index layers are alternately arranged. The third layer 500 may include an odd number of layers in total. In an embodiment, third layer 500 may include five layers, which may be arranged in the order of low/high/low/high/low refractive index, for example. The third layer 500 is illustrated as including five layers, but may include more or fewer layers. In an embodiment, the third layer 500 may include a first low-refractive-index layer 510, a first high-refractive-index layer 520, a second low-refractive-index layer 530, a second high-refractive-index layer 540, and a third low-refractive-index layer 550, sequentially arranged in the direction from the fingerprint-resistant layer 200 toward the substrate 100.

In an embodiment, the low-refractive-index layer at the lowermost position of the third layer 500 may improve adhesion to the substrate 100. In an embodiment, the lowermost low-refractive-index layer and the substrate 100 may include the same material (e.g., SiO₂), for example. Accordingly, the adhesion between the third layer 500 and the substrate 100 may be enhanced through the lowermost low-refractive-index layer of the third layer 500.

Due to the stacked structure of the first, second, and third layers 300, 600, and 500, is the AR coating layer may overall have a stacked structure in which a high-refractive-index layer is disposed between at least two low-refractive-index layers. Overall, the AR coating layer may include low-refractive-index layers at the uppermost and lowermost positions, and have a structure in which high- and low-refractive-index layers are alternately arranged. The AR coating layer may include an odd number of high- and low-refractive-index layers in total.

The low-refractive-index layer of the first layer 300, e.g., the first low-refractive-index layer 310, may include SiO₂. The refractive index of the low-refractive-index layer of the first layer 300 may be approximately 1.45 to 1.55. The thickness of the low-refractive-index layer of the first layer 300 may be approximately 80 nm to 120 nm.

The high-refractive-index layers of the high-hardness layers in the second layer 600, e.g., the first high-refractive-index layer 611 of the first high-hardness layer 610, the first high-refractive-index layer 631 of the second high-hardness layer 630, the first high-refractive-index layer 651 of the third high-hardness layer 650, and the first high-refractive-index layer 671 of the fourth high-hardness layer 670, may include at least one of ZrO₂, Ta₂O₅, or Si₃N₄. The refractive index of the high-refractive-index layers of the high-hardness layers in the second layer 600 may be approximately 1.8 to 2.1. The thickness of the high-refractive-index layers of the high-hardness layers in the second layer 600 may be approximately 40 nm to 500 nm.

The high-refractive-index layers of the intermediate layers in the second layer 600, e.g., the first high-refractive-index layer 622 of the first intermediate layer 620, may include at least one of ZrO₂, Ta₂O₅, or Si₃N₄. The refractive index of the high-refractive-index layers of the intermediate layers in the second layer 600 may be approximately 1.8 to 2.1. The thickness of the high-refractive-index layers of the intermediate layers in the second layer 600 may be 100 nm or less.

The low-refractive-index layers of the intermediate layers in the second layer 600, e.g., the first and second low-refractive-index layers 621 and 623 of the first intermediate layer 620, the first low-refractive-index layer 641 of the second intermediate layer 640, and the first low-refractive-index layer 661 of the third intermediate layer 660, may include at least one of SiO₂, Al₂O₃, or SiON. The refractive index of the low-refractive-index layers of the intermediate layers in the second layer 600 may be approximately 1.45 to 1.8. The thickness of the low-refractive-index layers of the intermediate layers in the second layer 600 may be 100 nm or less.

The high-refractive-index layers of the third layer 500, e.g., the first and second high-refractive-index layers 520 and 540, may include at least one of ZrO₂, Ta₂O₅, or Si₃N₄. The refractive index of the high-refractive-index layers of the third layer 500 may be approximately 1.8 to 2.1. The thickness of the high-refractive-index layers of the third layer 500 may be approximately 50 nm to 100 nm.

The low-refractive-index layers of the third layer 500, e.g., the first, second, and third low-refractive-index layers 510, 530, and 550, may include at least one of SiO₂, Al₂O₃, or SiON. The refractive index of the low-refractive-index layers of the third layer 500 may be approximately 1.45 to 1.8. The thickness of the low-refractive-index layers of the third layer 500 may be 100 nm or less.

In an embodiment, the AR coating layer of the cover window WM_1 according to the second embodiment may be formed by a sputtering deposition method.

FIG. 14A illustrates six embodiments of the second embodiment. The AR coating layer of a cover window WM_1 according to Embodiment 2a may include a total of nine layers, the AR coating layer of a cover window WM_1 according to Embodiment 2b may include a total of eleven layers, the AR coating layer of a cover window WM_1 according to Embodiment 2c may include a total of thirteen layers, the AR coating layer of a cover window WM_1 according is to Embodiment 2d may include a total of thirteen layers, the AR coating layer of a cover window WM_1 according to Embodiment 2e may include a total of thirteen layers, and the AR coating layer of a cover window WM_1 according to Embodiment 2f may include a total of fifteen layers.

In an embodiment, the hardness of the cover windows WM_1 according to Embodiments 2a, 2b, and 2c may be approximately 15 gigapascals (GPa), the hardness of the cover windows WM_1 according to Embodiments 2d and 2e may be approximately 17 GPa, and the hardness of the cover window WM_1 at Embodiment 2f may be approximately 18 GPa.

In this specification, hardness refers to the hardness of a target layer measured using a nanoindenter from Anton Paar in accordance with the ISO 14577-1 standard.

In an embodiment, as illustrated in FIG. 14A, in the cover window WM_1 according to the second embodiment, the thicknesses of the low-refractive-index layers may be smaller than the thicknesses of the high-refractive-index layers of the corresponding high-hardness layers next (adjacent) to the low-refractive-index layers. In an embodiment, the thickness of the first low-refractive-index layer 310 of the first layer 300 may be smaller than the thickness of the first high-refractive-index layer 611 of the first high-hardness layer 610 of the second layer 600, and the thickness of the first low-refractive-index layer 621 of the first intermediate layer 620 of the second layer 600 may be smaller than the thickness of the first high-refractive-index layer 611 of the first high-hardness layer 610 of the second layer 600, for example. In addition, the thickness of the second low-refractive-index layer 623 of the first intermediate layer 620 of the second layer 600 may be smaller than the thickness of the first high-refractive-index layer 631 of the second high-hardness layer 630 of the second layer 600.

In the first intermediate layer 620 of the second layer 600 of each of the cover windows WM_1 according to Embodiments 2a, 2b, and 2c, the thickness of the first high-refractive-index layer 622 may be greater than the thicknesses of the first and second low-refractive-index layers 621 and 623. That is, in each of the cover windows WM_1 according to Embodiments 2a, 2b, and 2c, the thicknesses of the layers in the low/high/low refractive index structure in the first intermediate layer 620 of the second layer 600 may increase and then decrease.

In the second layer 600 of each of the cover windows WM_1 according to Embodiments 2d and 2f, the thicknesses of the low- or high-refractive-index layers included in the first intermediate layer 620 may continuously decrease. In an embodiment, the thickness of the first low-refractive-index layer 621 of the first intermediate layer 620 of the second layer 600 may be greater than the thickness of the first high-refractive-index layer 622, and the thickness of the first high-refractive-index layer 622 may be greater than that of the second low-refractive-index layer 623, for example.

In the first intermediate layer 620 of the second layer 600 of the cover window WM_1 according to Embodiment 2e, the thickness of the first high-refractive-index layer 622 may be smaller than those of the first and second low-refractive-index layers 621 and 623. That is, in the cover window WM_1 according to Embodiment 2e, the thicknesses of the layers in the low/high/low refractive index structure in the first intermediate layer 620 of the second layer 600 may decrease and then increase.

According to the cover window WM_1 of the second embodiment, the chroma of the peripheral portions WM_B may be maintained at the same level as that of the front portion WM_P, even when the thickness of second peripheral portions CTL_B of the coating layer CTL varies depending on a first angle θw of peripheral portions WM_B, by adjusting the hardness of the cover window WM_1 and the thickness variation, stacking order, and refractive indices of the low-refractive-index layers and high-refractive-index layers in the cover window WM_1. In is an embodiment, as illustrated in FIG. 14B, the chroma of the peripheral portions WM_B may be maintained at approximately 4 or less, for example.

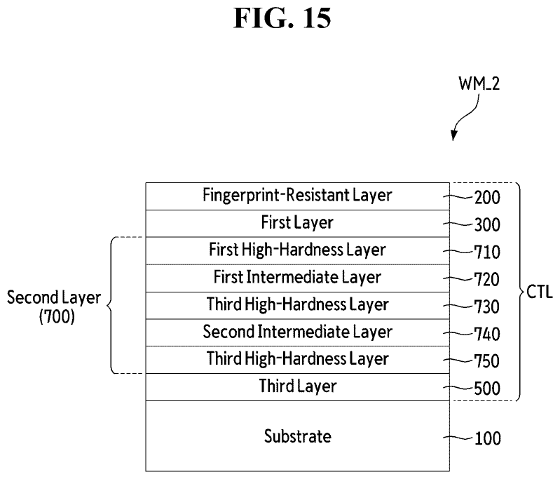

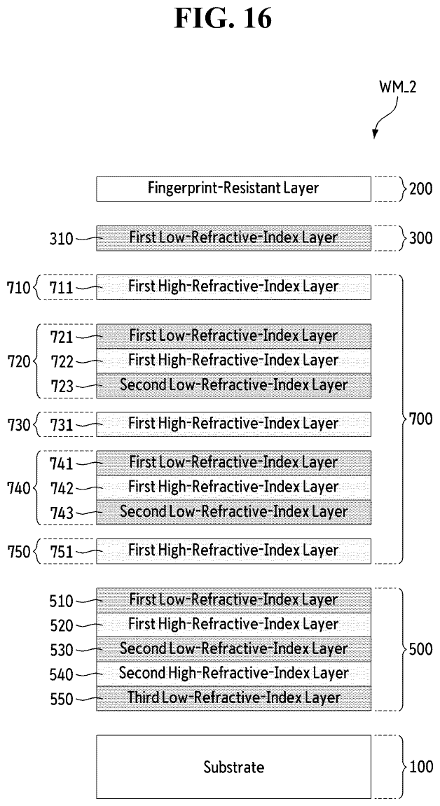

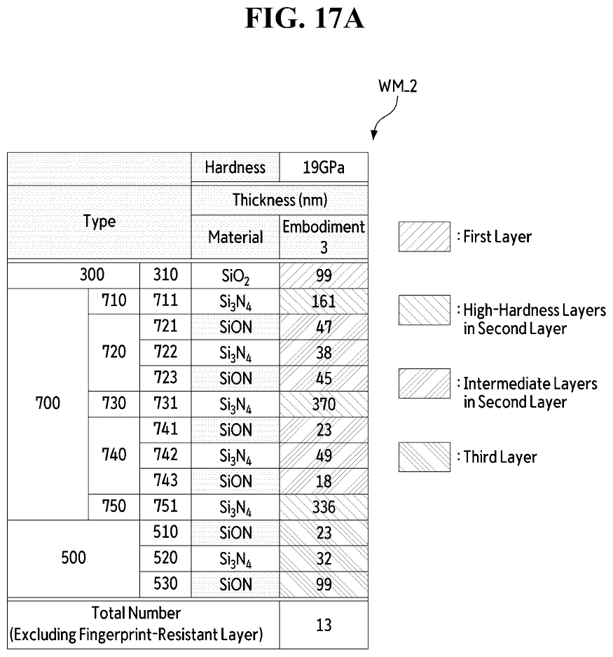

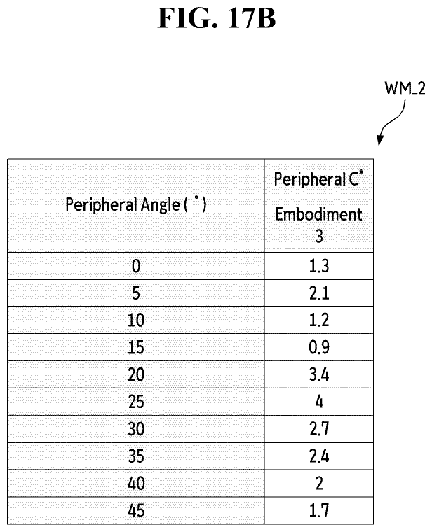

FIG. 15 is a block diagram illustrating a stacked structure of a cover window according to a third embodiment. FIG. 16 is a detailed block diagram illustrating the stacked structure of the cover window according to the third embodiment. FIG. 17A is a table illustrating the thickness of the front portion of the cover window according to the third embodiment. FIG. 17B is a table illustrating chroma by angle of the peripheral portions of the cover window according to the third embodiment.

Referring to FIGS. 15, 16, 17A, and 17B, a cover window WM_2 according to the third embodiment differs from the cover window WM_1 according to the second embodiment described with reference to FIG. 12 in the structure of a second layer 700.

Specifically, the second layer 700 of the cover window WM_2 according to the third embodiment differs in that it includes two intermediate layers. Specifically, the cover window WM_2 according to the third embodiment includes two intermediate layers each having a three-layer structure, i.e., a first intermediate layer 720 and a second intermediate layer 740, whereas the second layer 600 of the cover window WM_1 according to the second embodiment includes only one such intermediate layer, i.e., the first intermediate layer 620.

The second layer 700 of the cover window WM_2 according to the third embodiment includes five layers in total, combining high-hardness and intermediate layers. The second layer 700 may include a first high-hardness layer 710, a first intermediate layer 720, a second high-hardness layer 730, a second intermediate layer 740, and a third high-hardness layer 750, sequentially arranged in a direction from a fingerprint-resistant layer 200 toward a substrate 100.

A first high-hardness layer 710 of the second layer 700 may include a first high-refractive-index layer 711. A first intermediate layer 720 of the second layer 700 may include a first low-refractive-index layer 721, a first high-refractive-index layer 722, and a second low-refractive-index layer 723, sequentially arranged in the direction from the fingerprint-resistant layer 200 toward the substrate 100. The second high-hardness layer 730 may include a first high-refractive-index layer 731. The second intermediate layer 740 may include a first low-refractive-index layer 741, a first high-refractive-index layer 742, and a second low-refractive-index layer 743, sequentially arranged in the direction from the fingerprint-resistant layer 200 toward the substrate 100. The third high-hardness layer 750 may include a first high-refractive-index layer 751.

The high-refractive-index layers of the high-hardness layers in the second layer 700, e.g., the first high-refractive-index layer 711 of the first high-hardness layer 710, the first high-refractive-index layer 731 of the second high-hardness layer 730, and the first high-refractive-index layer 751 of the third high-hardness layer 750, may include at least one of ZrO₂, Ta₂O₅, or Si₃N₄. The refractive index of the high-refractive-index layers of the high-hardness layers in the second layer 700 may be approximately 1.8 to 2.1. The thickness of the high-refractive-index layers of the high-hardness layers in the second layer 700 may be approximately 40 nm to 500 nm.

The high-refractive-index layers of the intermediate layers in the second layer 700, e.g., the first high-refractive-index layer 722 of the first intermediate layer 720 and the first high-refractive-index layer 742 of the second intermediate layer 740, may include at least one of ZrO₂, Ta₂O₅, or Si₃N₄. The refractive index of the high-refractive-index layers of the intermediate is layers in the second layer 700 may be approximately 1.8 to 2.1. The thickness of the high-refractive-index layers of the intermediate layers in the second layer 700 may be 100 nm or less.

The low-refractive-index layers of the intermediate layers in the second layer 700, e.g., the first and second low-refractive-index layers 721 and 723 of the first intermediate layer 720 and the first and second low-refractive-index layers 741 and 743 of the second intermediate layer 740, may include at least one of SiO₂, Al₂O₃, or SiON. The refractive index of the low-refractive-index layers of the intermediate layers in the second layer 700 may be approximately 1.45 to 1.8. The thickness of the low-refractive-index layers of the intermediate layers in the second layer 700 may be 100 nm or less.

In an embodiment, the AR coating layer of the cover window WM_2 according to the third embodiment may be formed by a sputtering deposition method.

FIG. 17A illustrates one embodiment of the third embodiment. The AR coating layer of the cover window WM_2 according to the third embodiment may include thirteen layers. In an embodiment, the hardness of the cover window WM_2 according to the third embodiment may be approximately 19 GPa.

In the cover window WM_2 according to the third embodiment, the thicknesses of the low-refractive-index layers may be smaller than the thicknesses of the high-refractive-index layers of the corresponding high-hardness layers next (adjacent) to the low-refractive-index layers. In an embodiment, the thickness of the first low-refractive-index layer 310 of the first layer 300 may be smaller than the thickness of the first high-refractive-index layer 711 of the first high-hardness layer 710 of the second layer 700, and the thickness of the first low-refractive-index layer 721 of the first intermediate layer 720 of the second layer 700 may be smaller than the thickness of the first high-refractive-index layer 711 of the first high-hardness is layer 710, for example. In addition, the thickness of the second low-refractive-index layer 723 of the first intermediate layer 720 may be smaller than the thickness of the first high-refractive-index layer 731 of the second high-hardness layer 730, and the thickness of the first low-refractive-index layer 741 of the second intermediate layer 740 may be smaller than the thickness of the first high-refractive-index layer 731 of the second high-hardness layer 730.

In the first intermediate layer 720 of the second layer 700, the thickness of the first high-refractive-index layer 722 may be smaller than the thicknesses of the first and second low-refractive-index layers 721 and 723. That is, the thicknesses of the layers in the low/high/low refractive index structure in the first intermediate layer 720 may decrease and then increase.

In the second intermediate layer 740 of the second layer 700, the thickness of the first high-refractive-index layer 742 may be greater than the thicknesses of the first and second low-refractive-index layers 741 and 743. That is, the thicknesses of the layers in the low/high/low refractive index structure in the second intermediate layer 740 may increase and then decrease.

According to the cover window WM_2 of the third embodiment, the chroma of the peripheral portions WM_B may be maintained at the same level as that of the front portion WM_P, even when the thickness of second peripheral portions CTL_B of the coating layer CTL varies depending on a first angle θw of peripheral portions WM_B, by adjusting the hardness of the cover window WM_2, the thickness variation, stacking order, and refractive indices of the low-refractive-index layers and high-refractive-index layers. In an embodiment, as illustrated in FIG. 17B, the chroma of the peripheral portions WM_B may be maintained at approximately 4 or less, for example.

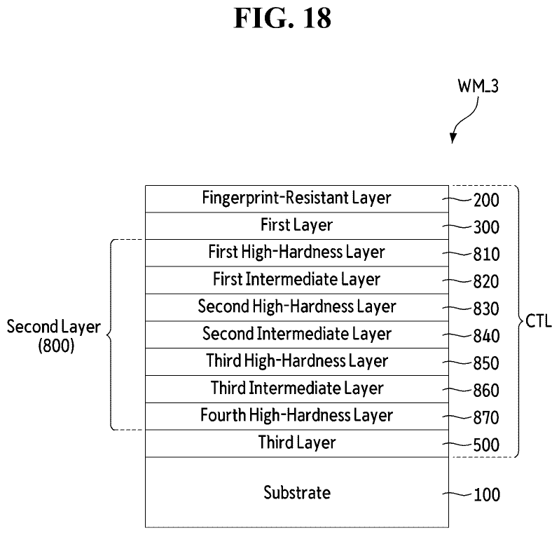

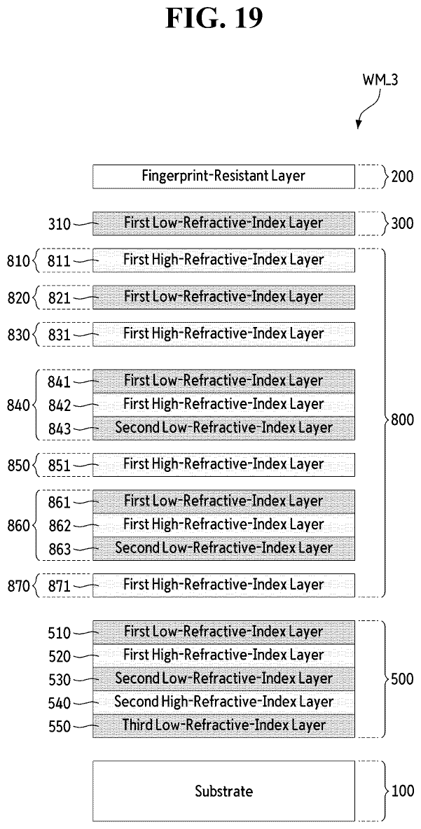

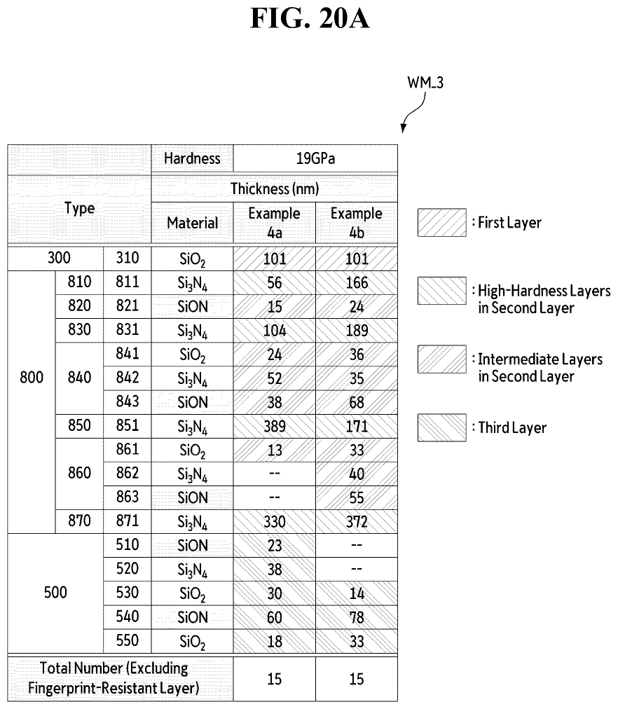

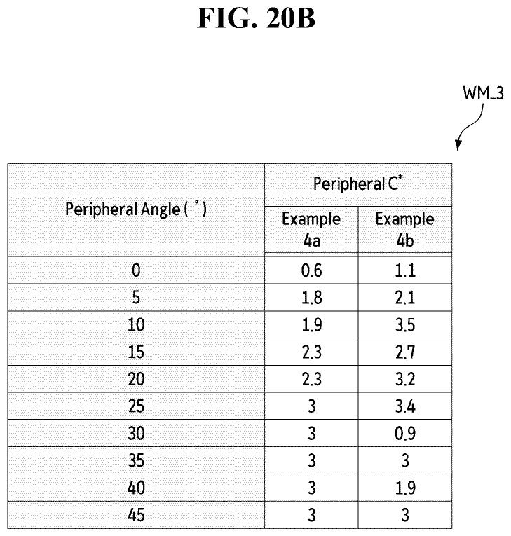

FIG. 18 is a block diagram illustrating a stacked structure of a cover window is according to a fourth embodiment. FIG. 19 is a detailed block diagram illustrating the stacked structure of the cover window according to the fourth embodiment. FIG. 20A is a table illustrating the thickness of the front portion of the cover window according to the second embodiment. FIG. 20B is a table illustrating chroma by angle of the peripheral portions of the cover window according to the second embodiment.

Referring to FIGS. 18, 19, 20A, and 20B, a cover window WM_3 according to the fourth embodiment differs from the cover window WM_1 according to the second embodiment described with reference to FIG. 12 and the cover window WM_2 according to the third embodiment described with reference to FIG. 15 in the structure of a second layer 800.

Specifically, the second layer 800 of the cover window WM_3 according to the fourth embodiment includes four high-hardness layers and three intermediate layers, whereas the second layer 700 of the cover window WM_2 according to the third embodiment described with reference to FIG. 15 includes three high-hardness layers and two intermediate layers. In addition, the second layer 800 of the cover window WM_3 according to the fourth embodiment includes one layer in the first intermediate layer 820, three layers in the second intermediate layer 840, and one or three layers in the third intermediate layer 860, whereas the second layer 600 of the cover window WM_1 according to the second embodiment includes three layers in the first intermediate layer 620, one layer in the second intermediate layer 640, and one layer in the third intermediate layer 660.

The second layer 800 of the cover window WM_3 according to the fourth embodiment includes seven layers in total, combining high-hardness and intermediate layers. The second layer 800 may include a first high-hardness layer 810, a first intermediate layer 820, a second high-hardness layer 830, a second intermediate layer 840, a third high-hardness layer 850, a third intermediate layer 860, and a fourth high-hardness layer 870, sequentially arranged in a direction from a fingerprint-resistant layer 200 toward a substrate 100.

The first high-hardness layer 810 of the second layer 800 may include a first high-refractive-index layer 811. The first intermediate layer 820 of the second layer 800 may include a first low-refractive-index layer 821. The second high-hardness layer 830 of the second layer 800 may include a first high-refractive-index layer 831. The second intermediate layer 840 of the second layer 800 may include a first low-refractive-index layer 841, a first high-refractive-index layer 842, and a second low-refractive-index layer 843. The third high-hardness layer 850 of the second layer 800 may include a first high-refractive-index layer 851, sequentially arranged in the direction from the fingerprint-resistant layer 200 toward the substrate 100. The third intermediate layer 860 of the second layer 800 may include a first low-refractive-index layer 861, a first high-refractive-index layer 862, and a second low-refractive-index layer 863, sequentially arranged in the direction from the fingerprint-resistant layer 200 toward the substrate 100. The fourth high-hardness layer 870 of the second layer 800 may include a first high-refractive-index layer 871. As illustrated in FIG. 20A, in the case of a cover window WM_3 according to Embodiment 4a, the first high-refractive-index layer 862 and the second low-refractive-index layer 863 of the third intermediate layer 860 may be omitted.

The third layer 500 of the cover window WM_3 according to the fourth embodiment may include three or five layers in total, combining high- and low-refractive-index layers. The third layer 500 may include a first low-refractive-index layer 510, a first high-refractive-index layer 520, a second low-refractive-index layer 530, a second high-refractive-index layer 540, and a third low-refractive-index layer 550, sequentially arranged in a direction from the fingerprint-resistant layer 200 toward the substrate 100. As illustrated in FIG. 20A, in the case of a cover window WM_3 according to Embodiment 4b, the second high-refractive-index layer 540 and the is third low-refractive-index layer 550 of the third layer 500 may be omitted.

The high-refractive-index layers of the high-hardness layers in the second layer 800, e.g., the first high-refractive-index layer 811 of the first high-hardness layer 810, the first high-refractive-index layer 831 of the second high-hardness layer 830, the first high-refractive-index layer 851 of the third high-hardness layer 850, and the first high-refractive-index layer 871 of the fourth high-hardness layer 870, may include at least one of ZrO₂, Ta₂O₅, or Si₃N₄. The refractive index of the high-refractive-index layers of the high-hardness layers in the second layer 800 may be approximately 1.8 to 2.1. The thickness of the high-refractive-index layers of the high-hardness layers in the second layer 800 may be approximately 40 nm to 500 nm.

The high-refractive-index layers of the intermediate layers in the second layer 800, e.g., the first high-refractive-index layer 842 of the second intermediate layer 840 and the first high-refractive-index layer 862 of the third intermediate layer 860, may include at least one of ZrO₂, Ta₂O₅, or Si₃N₄. The refractive index of the high-refractive-index layers of the intermediate layers in the second layer 800 may be approximately 1.8 to 2.1, and the thickness of the high-refractive-index layers of the intermediate layers in the second layer 800 may be 100 nm or less.

The low-refractive-index layers of the intermediate layers in the second layer 800, e.g., the first low-refractive-index layer 821 of the first intermediate layer 820, the first and second low-refractive-index layers 841 and 843 of the second intermediate layer 840, and the first and second low-refractive-index layers 861 and 863 of the third intermediate layer 860, may include at least one of SiO₂, Al₂O₃, or SiON. The refractive index of the low-refractive-index layers of the intermediate layers in the second layer 800 may be approximately 1.45 to 1.8. The thickness of the low-refractive-index layers of the intermediate layers in the second layer 800 may be 100 nm or less.

In an embodiment, the AR coating layer of the cover window WM_3 according to the fourth embodiment may be formed by a sputtering deposition method.

FIG. 20A illustrates two embodiments of the fourth embodiment. The AR coating layer of the cover window WM_3 according to Embodiment 4a may include fifteen layers, and the AR coating layer of the cover window WM_3 according to Embodiment 4b may also include fifteen layers. In an embodiment, the hardness of the cover window WM_3 according to the fourth embodiment may be approximately 19 GPa.

In the cover window WM_3 according to the fourth embodiment, the thicknesses of the low-refractive-index layers may be smaller than the thicknesses of the high-refractive-index layers of the respective high-hardness layers next (adjacent) to the low-refractive-index layers. In an embodiment, the thickness of the first low-refractive-index layer 310 of the first layer 300 may be smaller than the thickness of the first high-refractive-index layer 811 of the first high-hardness layer 810, and the thickness of the first low-refractive-index layer 821 of the first intermediate layer 820 may also be smaller than the thickness of the first high-refractive-index layer 811, for example.

However, the present invention is not limited thereto, and in some embodiments, the thickness of the first high-refractive-index layer 811 of the first high-hardness layer 810 may be smaller than the thickness of the first low-refractive-index layer 310 of the first layer 300, for example.

Also, the thickness of the first low-refractive-index layer 821 may be smaller than the thickness of the first high-refractive-index layer 831 of the second high-hardness layer 830, and the thickness of the first low-refractive-index layer 841 of the second intermediate layer 840 may be smaller than the thickness of the first high-refractive-index layer 831. The thickness of the second low-refractive-index layer 843 may be smaller than the thickness of the first high-refractive-index layer 851 of the third high-hardness layer 850, and the thickness of the first low-refractive-index layer 861 may be smaller than the thickness of the first high-refractive-index layer 851. Additionally, the thickness of the second low-refractive-index layer 863 may be smaller than the thickness of the first high-refractive-index layer 871 of the fourth high-hardness layer 870, and the thickness of the first low-refractive-index layer 510 of the third layer 500 may be smaller than the thickness of the first high-refractive-index layer 871.

In a second intermediate layer 840 of a second layer 800 of the cover window WM_3 according to Embodiment 4a, the thickness of a first high-refractive-index layer 842 may be greater than the thicknesses of first and second low-refractive-index layers 841 and 843. That is, the thicknesses of the layers in the low/high/low refractive index structure of the second intermediate layer 840 may increase and then decrease.

In a second intermediate layer 840 of a second layer 800 of the cover window WM_3 according to Embodiment 4b, the thickness of a first high-refractive-index layer 842 may be smaller than the thicknesses of first and second low-refractive-index layers 841 and 843. That is, the thicknesses of the layers in the low/high/low refractive index structure of the second intermediate layer 840 may decrease and then increase.

In a third intermediate layer 860 of the second layer 800 of the cover window WM_3 according to Embodiment 4b, the thicknesses of the low- or high-refractive-index layers may continuously increase. In an embodiment, the thickness of a first low-refractive-index layer 861 may be smaller than the thickness of a first high-refractive-index layer 862, and the thickness of the first high-refractive-index layer 862 may be smaller than the thickness of a second low-refractive-index layer 863, for example.

According to the cover window WM_3 of the fourth embodiment, the chroma of is peripheral portions WM_B may be maintained at the same level as that of a front portion WM_P, even when the thickness of second peripheral portions CTL_B of a coating layer CTL varies depending on a first angle θw of the peripheral portions WM_B, by adjusting the hardness, thickness variation, stacking order, and refractive indices of the low- and high-refractive-index layers. In an embodiment, as illustrated in FIG. 20B, the chroma of the peripheral portions WM_B may be maintained at approximately 4 or less, for example.

The display device DD may be applied to various electronic devices. An electronic device 1 in an embodiment may include the display device DD and may further include a module or device having additional functions, in addition to the display device DD.

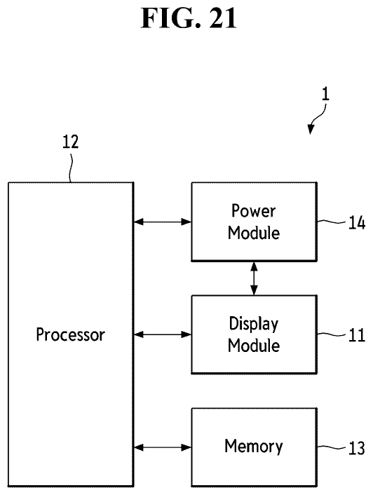

FIG. 21 is a block diagram of an embodiment of an electronic device.

Referring to FIG. 21, the electronic device 1 may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), or a controller.

The memory 13 may store data and information desired for operation of the processor 12 or display module 11. When the processor 12 executes an application stored in the memory 13, video data signals and/or input control signals may be delivered to the display module 11, and the display module 11 may process the received signals and output image information via a display screen.

The power module 14 may include a power supply module, such as a power adapter or battery device, and a power conversion module for converting the supplied power into power desired for the operation of the electronic device 1.

At least one of the components of the electronic device 1 described above may be is included in the display device DD. Also, among the individual modules functionally grouped in a single module, some may be included in the display device DD and others may be provided separately. In an embodiment, the display device DD may include the display module 11, while the processor 12, the memory 13, and the power module 14 may be provided as other devices than the display device DD, within the electronic device 1, for example.

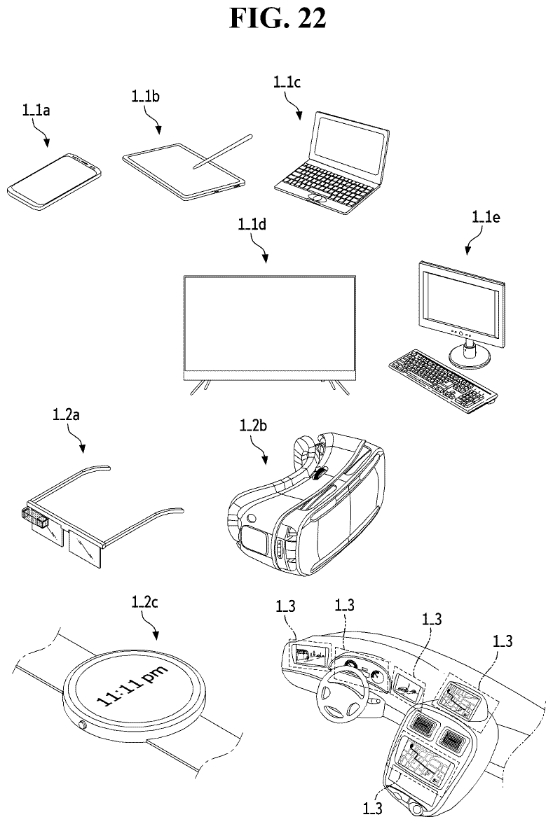

FIG. 22 is a set of schematic views of embodiments of electronic devices.

Referring to FIG. 22, various electronic devices 1 to which the display device DD is applicable may include image display electronic devices 1 such as a smartphone 1_1a, a tablet personal computer (“PC”) 1_1b, a laptop 1_1c, a television (“TV”) 1_1d, and a desktop monitor 1_1e, wearable electronic devices 1 including a display module, such as smart glasses 1_2a, a head-mounted display 1_2b, and a smartwatch 1_2c, and vehicle electronic devices 1_3 including a display module, such as an instrument cluster, a center fascia, a center information display (“CID”) arranged on the dashboard, or a room mirror display.

In concluding the detailed description, those skilled in the art will appreciate that many variations and modifications may be made to the preferred embodiments without substantially departing from the principles of the disclosure. Therefore, the disclosed preferred embodiments of the disclosure are used in a generic and descriptive sense only and not for purposes of limitation.

What is claimed is:

1. A cover window comprising:
a front portion;
a peripheral portion bent from the front portion and disposed on one side of the front portion;
a substrate; and
a coating layer disposed on the substrate, the coating layer including:
a first layer disposed at an uppermost position, the first layer including:
a low-refractive-index layer;
a second layer disposed below the first layer, the second layer including:
at least two high-refractive-index layers; and
a low-refractive-index layer disposed between the at least two high-refractive-index layers; and
a third layer disposed below the second layer, the third layer including:
at least two low-refractive-index layers; and
a high-refractive-index layer disposed between the at least two low-refractive-index layers.

2. The cover window of claim 1, wherein ratios of tristimulus values of reflected light to tristimulus values of reference light in the peripheral portion are the same as ratios of tristimulus values of the reflected light to tristimulus values of the reference light in the front portion.

3. The cover window of claim 2, wherein chroma of the peripheral portion is the same as chroma of the front portion.

4. The cover window of claim 3, wherein a thickness of the coating layer in the peripheral portion is less than or equal to a thickness of the coating layer in the front portion.

5. The cover window of claim 4, wherein
the first layer includes SiO₂,
a thickness of the first layer is 80 nanometers to 120 nanometers, and
a refractive index of the first layer is 1.4 to 1.55.

6. The cover window of claim 5, wherein
the high-refractive-index layer includes at least one of ZrO₂, Ta₂O₅, Si₃N₄, TiO₂, or Ti₃O₅,
a thickness of the high-refractive-index layer is 5 nanometers to 90 nanometers, and
a refractive index of the high-refractive-index layer is 1.8 to 2.5.

7. The cover window of claim 6, wherein
the low-refractive-index layer of the second layer includes at least one of SiO₂, Al₂O₃, or SiON,
a thickness of the low-refractive-index layer is 5 nanometers to 90 nanometers, and
a refractive index of the low-refractive-index layer is 1.45 to 1.7.

8. The cover window of claim 7, wherein
the coating layer further includes a fingerprint-resistant layer disposed on the first layer, and
the fingerprint-resistant layer includes perfluoropolyether.

9. The cover window of claim 8, wherein
the second layer includes a first high-refractive-index layer, a first low-refractive-index layer, and a second high-refractive-index layer, sequentially arranged from a side farther from the substrate, and
a thickness of the first low-refractive-index layer is smaller than thicknesses of the first and second high-refractive-index layers.

10. A cover window comprising:
a front portion;
a peripheral portion bent from the front portion and disposed on one side of the front portion;
a substrate; and
a coating layer disposed on the substrate, the coating layer including:
a first layer disposed at an uppermost position, the first layer including:
a low-refractive-index layer;
a second layer disposed below the first layer, the second layer including:
at least two high-hardness layers; and
at least one intermediate layer disposed between the at least two high-hardness layers; and
a third layer disposed below the second layer, the third layer including:
at least two low-refractive-index layers; and
at least one high-refractive-index layer disposed between the at least two low-refractive-index layers.

11. The cover window of claim 10, wherein ratios of tristimulus values of reflected light to tristimulus values of reference light in the peripheral portion are the same as ratios of tristimulus values of the reflected light to tristimulus values of the reference light in the front portion.

12. The cover window of claim 11, wherein chroma of the peripheral portion is the same as chroma of the front portion.

13. The cover window of claim 12, wherein a thickness of the coating layer in the is peripheral portion is less than or equal to a thickness of the coating layer in the front portion.

14. The cover window of claim 13, wherein
the first layer includes SiO₂,
a thickness of the first layer is 80 nanometers to 120 nanometers, and
a refractive index of the first layer is 1.45 to 1.55.

15. The cover window of claim 14, wherein
a high-hardness layer of the at least two high-hardness layers includes at least one of ZrO₂, Ta₂O₅, Si₃N₄, TiO₂, or Ti₃O₅,
a thickness of the high-hardness layer is 40 nanometers to 500 nanometers, and
a refractive index of the high-hardness layer is 1.8 to 2.1.

16. The cover window of claim 15, wherein
the low-refractive-index layer includes at least one of SiO₂, Al₂O₃, or SiON,
a thickness of the low-refractive-index layer is 100 nanometers or less, and
a refractive index of the low-refractive-index layer is 1.45 to 1.8.

17. The cover window of claim 16, wherein
the coating layer further includes a fingerprint-resistant layer disposed on the first layer, and
the fingerprint-resistant layer includes perfluoropolyether.

18. The cover window of claim 17, wherein
the at least one intermediate layer includes at least two low-refractive-index layers and at least one high-refractive-index layer disposed between the at least two low-refractive-index layers of the at least one intermediate layer, and
a thickness of the low-refractive-index layer of the at least one intermediate layer is smaller than a thickness of the high-hardness layer.

19. The cover window of claim 18, wherein a thickness of the low-refractive-index layer next to the high-hardness layer is smaller than a thickness of the high-hardness layer.

20. An electronic device comprising:
a display device including:
a display panel; and
a cover window disposed on the display panel, the cover window including:
a front portion;
a peripheral portion bent from the front portion and disposed on one side of the front portion;
a substrate; and
a coating layer disposed on the substrate, the coating layer including:
a first layer disposed at an uppermost position, the first layer including:
a low-refractive-index layer;
a second layer disposed below the first layer, is the second layer including:
at least two high-refractive-index layers; and
a low-refractive-index layer disposed between the at least two high-refractive-index layers; and
a third layer disposed below the second layer, the third layer including:
at least two low-refractive-index layers; and
a high-refractive-index layer disposed between the at least two low-refractive-index layers;
a processor configured to provide an image driving signal to the display panel; and
a power module configured to supply power to the display panel and the processor.
